(19) United States
(12) Patent Application Publication
(10) Pub. No.: US 2024/0387371 A1
(43) Pub. Date: Nov. 21, 2024

(54) 2-DIMENSIONAL MATERIALS AS BARRIER LAYERS IN METALLIZATION OF SEMICONDUCTOR DEVICES AND METHODS OF FORMING

(71) Applicant: Tokyo Electron Limited, Tokyo (JP)

(72) Inventors: Kandabara Tapily, Albany, NY (US); Gerrit Leusink, Albany, NY (US); Robert Clark, Leuven (BE)

(21) Appl. No.: 18/620,089

(22) Filed: Mar. 28, 2024

Related U.S. Application Data
(60) Provisional application No. 63/467,833, filed on May 19, 2023.

(51) Int. Cl. H01L 23/528; H01L 21/768

(52) U.S. Cl. CPC H01L 23/5283; H01L 21/76852; H01L 21/76856

(57) ABSTRACT

A semiconductor device including at least one barrier-protected metal feature and related methods of fabrication are described. A method of making a semiconductor device includes forming a barrier layer by steps including providing a metal precursor layer and converting the metal precursor layer into one or more two-dimensional monolayers including at least one chalcogenide. The method also includes causing the barrier layer to be in contact with at least one metal feature in a manner effective to provide the at least one barrier-protected metal feature.

### CROSS-REFERENCE TO RELATED APPLICATIONS

The application claims priority to U.S. Provisional Patent Application with Ser. No. 63/467,833 titled “2-DIMENSIONAL MATERIALS AS CAPPING LAYERS IN METALLIZATION OF SEMICONDUCTOR DEVICES AND METHOD OF FORMING” filed May 19, 2023, the entire contents of which are incorporated by reference for all purposes herein.

### FIELD

The present invention relates to semiconductor devices and methods for manufacturing semiconductor devices incorporating metallization features, and more particularly, to using ultrathin chalcogenide materials, preferably two-dimensional (2D) monolayer chalcogenide-based semiconductor materials as barrier layers in semiconductor device metallization.

### BACKGROUND

Metal features in microelectronic devices include contacts and interconnects (i.e., wiring). Metal features in semiconductor devices can be formed by strategies such as damascene techniques and/or metal patterning techniques. In damascene techniques, trenches and vias are formed in a dielectric material, such as by etching, and then the trenches and vias are filled with metal, such as copper or other metal. Patterning techniques involve patterning metal films to form patterned or raised metal features, typically by etching. In contrast to other electrically conductive metals used to form interconnects and contacts in semiconductor devices, copper (Cu) is challenging to etch. Accordingly, damascene strategies often are used to form copper features. Damascene or patterning techniques are used with other metals.

Damascene techniques include dual damascene, single damascene, and semi-damascene strategies. The “single” damascene process involves creating and filling the trenches (or vias) first and then proceeding to fill the trenches (or vias). Then, the etching and filling is repeated for the vias (or trenches). “Dual” damascene forms the trenches and vias at the same time and then fills both the trench and vias at the same time.

As semiconductor device feature size continues to scale to smaller sizes, it is becoming an increasing challenge to reduce the device contact resistance, especially for tight metal pitch using the conventional dual or single damascene flow strategies. Some aspects of next generation metallization are using semi damascene or subtractive metal etch flow. In these, Cu (and/or other metal) and damascene techniques are used to form some metal features while alternate metals to Cu that can be more easily etched, such as Al, Mo, Ru, and/or W, are deposited and then etched to form patterned metal features. In short, semi-damascene strategies form some metal features using patterning, and other metal features are formed using damascene techniques. A semi-damascene flow can enable tighter pitch dimensions, but drawbacks have remained, including inelastic electron surface scattering.

Copper and other metals face other challenges when used in semiconductor device fabrication to form metal features such as interconnects and contacts. These other challenges include electromigration, a phenomenon where the metal atoms are displaced under the influence of high current densities. This can cause diffusion of metal atoms into the surrounding dielectric materials, which can degrade device performance. Copper (Cu) is a typical metal used to form semiconductor interconnects, and is one example of a substance that tends to infiltrate conventional materials during variations of the damascene process.

To address these issues, both metal patterning and damascene processes use barrier layers. The barriers serve one or more purposes including: 1) preventing metal atoms such as copper atoms from diffusing into surrounding materials, and 2) maintaining the integrity of the device's structure and performance. Without such barriers, the diffusion of a metal such as copper into nearby dielectrics could lead to problems such as increased resistance and leakage currents, significantly impacting the reliability and lifespan of the device.

Barrier layers are prone to drawbacks, such as inelastic electron surface scattering mentioned above. Inelastic electron surface scattering is believed to involve at least some electrons interacting with or generating phonons, quanta of vibrational energy in a material, instead of conducting. Inelastic surface scattering has become an increasing challenge to optimize contact resistance with respect to such diffusion barriers.

Additionally, it also is believed that the generation of phonons in a material lattice due to inelastic scattering has a two-fold effect on conductivity. The scattering process itself removes energy from the electrons, reducing their mobility and thus the material's electrical conductivity. The increased phonon activity (i.e., vibrations in the lattice) also is believed to further scatter other electrons, leading to additional resistance to the flow of electric current. These effects become particularly important in nanoscale materials. As the size of the material decreases, the surface area to volume ratio increases. This tends to make surface scattering effects more relatively dominant. This is one reason why the electrical properties of nanostructured materials can differ significantly from their bulk counterparts.

Another problem concerns using barrier layers with smaller metal features in smaller nodes. Conventional strategies of forming barrier layers may not leave enough room to form effective metal features. Stated differently, a conventional barrier layer might be too thick and could take up too much of the available volume in trenches and vias with respect to smaller nodes and the corresponding tighter spacing requirements.

The emergence of two-dimensional (2D), materials with an atomically thin monolayer structure is of interest in the microelectronic field. These 2D monolayer materials possess electronic and optical properties that are useful for applications in semiconductor devices. 2D monolayer structures have been formed from a variety of materials ranging from semi-metal graphene to semiconducting transition metal dichalcogenides (TMDs) of sulfur, selenium, and/or tellurium and to insulating hexagonal boron nitride (h-BN).

Certain 2D diffusion barriers have been studied for use with semiconductor metallization. However, challenges and drawbacks such as excessive consumption of underlying metals, limited metallization options, and limited control into bulk materials, among others, have remained drawbacks. See, e.g., Lo et. Al., Opportunities and challenges of 2D Materials in back-end-of-line interconnect scaling, J. Appl. Phys. 128, 080903 (2020), https://doi.org/10.1063/5.0013737. However, controlling the depth of such surface modifications and being able to consistently form 2D surface modifications are challenging.

Thus, there is a particular need in the art for extremely thin barrier layers useful in microelectronic metallization that address the drawbacks of the prior art, and which reduce, avoid or otherwise minimize drawbacks such as inelastic surface electron scattering while providing conductance and beneficial aspects for semiconductor applications. There remains a strong need to be able to form effective barrier layers, particularly 2D barrier layers, with higher precision, control and uniformity. The needs are strongest with respect to smaller nodes (e.g., 10 nm or less or even 5 nm or less), where maximizing the volume available for metallization features and minimizing the amount of such volume taken up by barrier materials, are key objectives.

### SUMMARY

The present invention provides strategies that allow ultrathin barrier layers (e.g., layers having a thickness up to about 10 nm, or up to about 8 nm, or up to about 5 nm, or up to about 2 nm) to be formed more easily and with higher precision and control. The barrier layers are useful as barriers in metallization, particularly with respect to smaller nodes (e.g., nodes up to 20 nm, or up to 10 nm, or up to 5 nm, or up to 4 nm, or up to 3 nm, or even less).

Aspects of the invention involve forming barrier layers including one or more metal chalcogenides comprising one or more of S, Se, and/or Te, preferably dichalcogenides comprising one or more of S, Se, and/or Te, more preferably transition metal dichalcogenides comprising one or more of S, Se, and/or Te. In illustrative embodiments, transition metal dichalcogenides useful in the practice of the present invention are semiconductors. Strategies of the present invention include forming a thin precursor (e.g., metal, metal oxide, metal nitride, metal oxynitride, or the like) coating and then converting at least a portion of the precursor coating into one or more chalcogenides. Use of a precursor layer allows the thickness of the barrier layer to be more precisely controlled than if, for example, a metallization feature was to be directly reacted with chalcogens to achieve a surface modification, or if chalcogenide(s) were to be directly deposited. In practical effect, the interface between the precursor layer and the adjacent material significantly helps to allow the precursor material to be converted into the desired barrier material with useful selectivity relative to the adjacent material. Alternatively stated, the presence of the interface and precursor coating allows the depth and character of the chalcogenization to be better controlled than if the precursor coating was not used. The interface would help to provide improved chalcogenization control even if the material of the precursor and the adjacent material are similar, but the interface provides even more beneficial selectivity when the precursor material is different from the adjacent material.

Advantageously, the strategies of the present invention are useful to form barrier layers in the form of a 2D monolayer formed from at least one chalcogenide or a stack of such 2D monolayers. In some embodiments, each 2D monolayer in a stack may incorporate a different chalcogenide composition than other layers in the stack in order customize properties exhibited by different regions of the barrier layer.

Conventionally, chalcogens include oxygen (O), sulfur(S), selenium (Se), and tellurium (Te). However, in the practice of the present invention, oxygen is not considered to be a chalcogen. Metal oxides, however, are useful as described below as dielectric materials or as a least a portion of precursor materials in the formation of chalcogenides including one or more of S, Se, and/or Te.

Principles of the present invention are useful to provide a 2D monolayer-based material as a barrier layer in any metallization method, such as with respect to patterned metal features and/or damascened metal features. Practice of the present invention help to alleviate problems associated with the tighter pitch dimensions associated with damascene techniques and patterning techniques such as by reducing inelastic electron surface scattering and reducing electromigration. Barrier layers incorporating 2D monolayer-based material also can help to alleviate tight spacing constraints, thus improving upon conventional metal and metal nitride barrier and liner layers.

According to a first aspect of the present disclosure, a method of fabricating a semiconductor device including at least one barrier-protected metal feature is disclosed. According to the first aspect, the method includes the step of a) forming a barrier layer by steps including 1) providing a metal precursor layer, and 2) converting the metal precursor layer into one or more two-dimensional monolayers including at least one chalcogenide. The method also includes the step of b) causing the barrier layer to be in contact with at least one metal feature in a manner effective to provide the at least one barrier-protected metal feature.

According to a second aspect of the present disclosure, a method for forming a semiconductor device is disclosed. According to the second aspect the method includes a) providing a metal feature on a substrate. The method also includes b) forming a metal precursor layer on an exposed surface of the metal feature. The method further includes c) chalcogenizing at least a portion of the metal precursor layer under conditions effective to provide a barrier layer including at least one two-dimensional monolayer to provide a barrier-protected metal feature, where the at least one two-dimensional monolayer includes a metal chalcogenide.

According to a third aspect of the present disclosure, a method for forming a semiconductor device is disclosed. According to the third aspect, the method includes providing a dielectric feature on a substrate. The method also includes forming a metal precursor layer on an exposed surface of the dielectric feature. The method further includes chalcogenizing at least a portion of the metal precursor layer under conditions effective to provide a barrier layer including at least one two-dimensional monolayer to provide a barrier-protected dielectric feature, where the at least one two-dimensional monolayer includes a chalcogenide. The method also includes providing a conductive metal by a damascene process in contact with the barrier layer.

According to a fourth aspect of the present disclosure, a semiconductor device is disclosed. According to the fourth aspect, the semiconductor device includes a metal feature on a substrate. The semiconductor device also includes a barrier layer in contact with a surface of the metal feature, the barrier layer including one or more monolayers of two-dimensional material including a chalcogenide. According to the fourth aspect, the barrier is formed on the surface of the metal feature by providing a metal precursor layer on the surface of the metal feature, and converting the metal precursor layer into the one or more two-dimensional monolayers including the chalcogenide.

These and various other features and advantages will be apparent from a reading of the following detailed description.

### BRIEF DESCRIPTION OF THE DRAWINGS

The present invention will be further explained with reference to the appended Figures, wherein like structure is referred to by like numerals throughout the several views, and wherein:

FIGS. 1A-1H schematically shows the steps of a method of the present invention for applying a barrier coating of the present invention onto patterned metal features.

FIGS. 2A-2H schematically shows the steps of an alternative method of the present invention for applying a barrier coating of the present invention onto patterned metal features.

FIGS. 3A-3D schematically shows the steps of a method of the present invention for applying barrier layers of the present invention as caps on patterned metal features.

FIGS. 4A-4D schematically shows the steps of an alternative method of the present invention for applying barrier layers of the present invention as caps on patterned metal features.

FIG. 5 is a flowchart that schematically shows a method of integrating principles of the present invention into metallization strategies.

FIGS. 6A-6F schematically shows the steps of a method of the present invention for forming a barrier layer between a patterned dielectric material and metal features in a damascene process.

FIG. 7 is a flowchart that schematically shows a method of integrating principles of the present invention into damascene metallization strategies.

### DETAILED DESCRIPTION

The present invention will now be further described with reference to the following illustrative embodiments. The embodiments of the present invention described below are not intended to be exhaustive or to limit the invention to the precise forms disclosed in the following detailed description. Rather a purpose of the embodiments chosen and described is so that the appreciation and understanding by others skilled in the art of the principles and practices of the present invention can be facilitated.

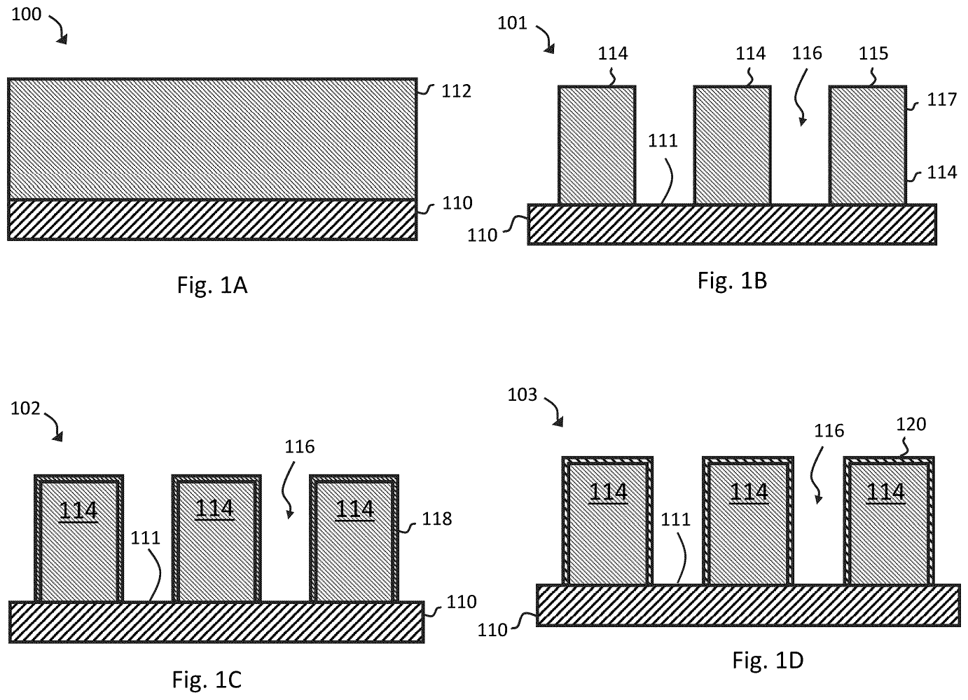

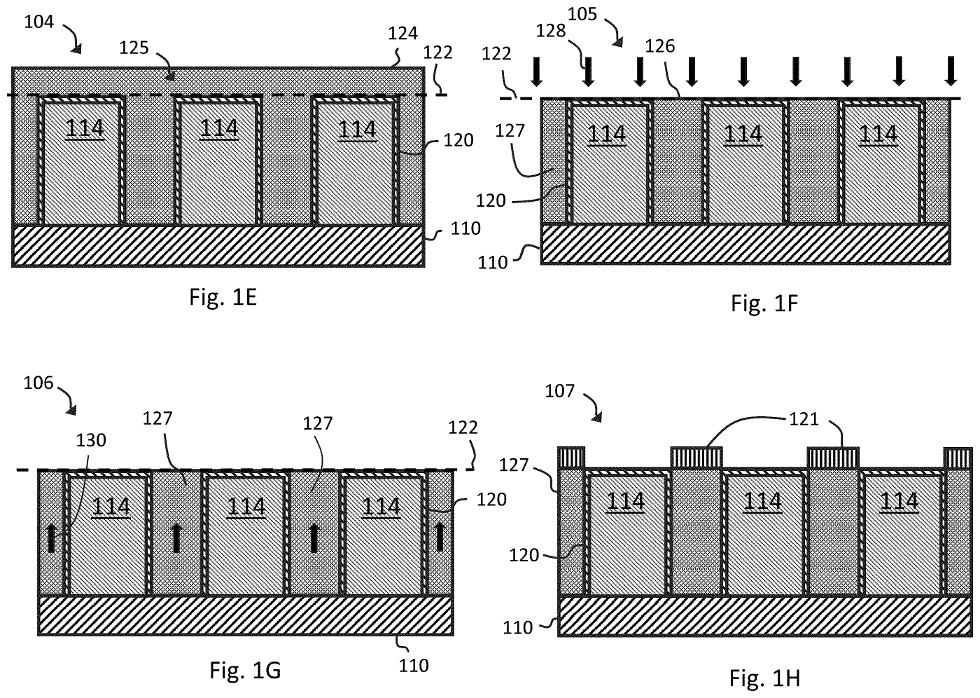

According to an illustrative embodiment of the present invention, FIGS. 1A through 1H schematically show through cross-sectional views a method of forming an ultrathin, barrier in the metallization of a semiconductor device. Each of the Figures shows the device as a workpiece in a stage of manufacture to achieve the metallization. Preferably, the barrier comprises at least one chalcogenide that comprises one or more of S, Se, and/or Te. Preferably the chalcogenide is a metal chalcogenide comprising one or more of S, Se, and/or Te. More preferably, the chalcogenide is a metal dichalcogenide comprising one or more of S, Se, and/or Te. In illustrative embodiments, the chalcogenide is a semiconductor.

The method of FIGS. 1A through 1H is described with respect to forming such a chalcogenide barrier, preferably in a form including one or more monolayers of 2D chalcogenide material, as a barrier layer for raised, metal features in a semiconductor device. Advantageously, the presence of the barrier layers, particularly those that include one or more monolayers of 2D material in preferred embodiments, can reduce inelastic surface scattering and may be able to replace conventional metal and metal nitride barrier and liner layers.

As known in the field of microelectronics, 2D materials are materials having a monolayer structure, preferably a monolayer structure in which the atoms in the monolayer are held together by relatively strong, in-plane covalent bonds. If a stack of such 2D monolayers is used, the in-plane intralayer bonds tend to be stronger than the relatively weaker out-of-plane interlayer bonds. It is believed that the out-of-plane bonds between monolayers may include Van der Waals bonds to help connect one monolayer to an adjacent monolayer (if present). See, e.g., U.S. Pat. No. 11,688,605; U.S. Pat. Pub. No. 2021/0376134. If a stack of 2D monolayers has been formed, one or more individual monolayers in a stack of monolayers can easily be removed due to the relatively weaker interlayer bonds, such as by breaking the Van der Waals bonds if present.

In accordance with the teachings of the present invention, 2D monolayers comprising a (e.g., a semiconductor in some modes of practice) chalcogenide are ultrathin and yet are capable of providing excellent barrier properties for metallization when used singly or in a stack of monolayers. A single sheet (layer) of a 2D material can be only a few Angstroms thick and yet could still adequately provide a good diffusion energy barrier to metals and metal ions, for example Cu. 2D materials also would be able to reduce the impact of surface scattering in electron transport that can degrade electrical resistivity.

Because of their ultrathin nature, such barriers occupy a relatively low volume. This advantageously leaves more room to provide metal features protected by the barrier. The ability of the ultrathin materials to form an effective barrier is particularly advantageous in smaller nodes where space for features is limited. 2D, transition metal dichalcogenide (TMD)-based materials are generally conductive or semiconductive. Furthermore, 2D monolayer materials comprising at least one transition metal dichalcogenide tend to have relatively high diffusion energy, making it difficult for other elements to interact with such 2D monolayers.

Although various embodiments herein discuss the presence of 2D monolayers or stacked layers thereof, it should be understood that barrier materials of the present invention may only partially contain 2D material. More preferably, though, barrier materials of the present invention are as close to being fully 2D monolayer-based as possible to help achieve more optimal performance.

FIGS. 1A through 1H schematically show how to form a single 2D monolayer as a barrier layer 120. In some modes of practice, if a barrier layer 120 comprising stack of two or more of such 2D monolayers is desired, the steps of FIGS. 1C and 1D would be repeated for each desired additional monolayer. This mode could be advantageous to provide multiple monolayers of the same or different 2D composition. In some modes of practice, if a barrier layer 120 comprising stack of two or more of such 2D monolayers is desired, a thicker precursor layer could be formed in step 1C, and proceeding to step 1D would provide a stack of two or more monolayers. For example, the steps of FIGS. 1C and 1D may be carried out in a manner effective to provide at least 1 monolayer or at least 2 or more monolayers such as 2 to 35 monolayers, or 2 to 20 monolayers, or 2 to 10 monolayers, or 2 to 8 monolayers.

An excess number of monolayers can be formed after which one or more of the excess monolayers can be removed to achieve a desired final form and thickness. This allows formation of exceptionally uniform barrier layers 120 that have precisely the same thickness within a device and from device to device, which in turn provides exceptionally uniform device performance. Precise removal of whole 2D monolayers can be achieved because of the relatively weaker bonds that couple 2D monolayers together as compared to the much stronger bonds within each 2D monolayer.

FIG. 1A schematically shows the step of providing an in-process semiconductor device 100 (a portion of a semiconductor device 100 is shown). The partially manufactured device 100 includes a film structure containing a metal layer 112 on a substrate 110. The substrate 110 can be any in-progress device at a stage of fabrication involving metallization. For example, substrate 110 may include various parts and components, including contacts, transistors, capacitors, interconnects, other circuitry, or portions thereof.

Metal layer 112 may include one or more electrically conductive metals suitable for forming metal features such as contacts and interconnects in semiconductor devices. The metals may include one or more transition metals. For example, the metal layer 112 can include one or more of the following metals: copper (Cu), cobalt (Co), ruthenium (Ru), molybdenum (Mo), tungsten (W), nickel (Ni), hafnium (Hf), aluminum (Al), Scandium (Sc), Titanium (Ti), Vanadium (V), Manganese (Mn), Cobalt (Co), Nickel (Ni), Zinc (Zn), Yttrium (Y), Zirconium (Zr), Niobium (Nb), Technetium (Tc), Rhodium (Rh), Palladium (Pd), Silver (Ag), Tantalum (Ta), Rhenium (Re), Osmium (Os), Iridium (Ir), Platinum (Pt), Gold (Au), or combinations thereof. Alloys of such metals may be used. For example, metal layer 112 can include a NiAl alloy, and/or a CuAl alloy. In preferred embodiments, metal layer 112 includes one or more of the following metals: copper (Cu) metal, aluminum (Al), cobalt (Co) metal, ruthenium (Ru) metal, molybdenum (Mo) metal, tungsten (W) metal, nickel (Ni) metal, rhodium (Rh), iridium (Ir), or alloys thereof, or combinations thereof.

As shown schematically in FIG. 1B, the method further includes patterning the metal layer 112 to form raised metal features 114 on the substrate 110 to provide the workpiece structure 101. As schematically shown, metal features 114 are patterned to include voids 116 that extend through metal layer 112 to substrate 110 exposing substrate surfaces 111. However, some voids 116 may extend only partially (not shown) through metal layer 112.

The patterning techniques used to form structure 101 may include the steps (not shown) of forming a photoresist layer over the metal layer 112, patterning the photoresist layer using lithography techniques to form a mask layer, using the resulting mask layer and subtractive techniques such as metal etching to form the patterned metal features 114 on the substrate 110, and then removing the mask material. The resulting raised metal features 114 contain top surfaces 115 and sidewall surfaces 117.

As shown schematically in FIG. 1C, the method further includes a step that comprises selectively forming a metal precursor layer 118 on exposed surfaces of the metal features 114 to thereby convert structure 101 into 102. The metal precursor layer 118 may be provided selectively onto the metal features 114 relative to exposed surfaces 111 of the underlying substrate 110.

Thus, rather than directly form barrier layer 120 of FIG. 1D on the metal features 114, the method of the present invention proceeds through the metal precursor layer 118 of FIG. 1C as an intermediate that is thereafter converted into the desired barrier layer 120. Using a method that proceeds through metal precursor layer 118 as an intermediate makes it easier to form 2D monolayers and to do so with more uniformity, control and precision as compared to methods that would attempt to surface modify metal features 114 themselves to form the barrier more directly or through direct deposition of a 2D structure onto the metal features 114. As another advantage, the practice of the present invention avoids unduly consuming metal features 114, which in turn avoids unduly increasing metal line resistivity.

A further advantage is increased flexibility of options for providing 2D materials. For example, practice of the present invention could allow a 2D dichalcogenide such as MoS₂ on Ru metal lines; or a stack of MoS₂/WS₂ on Ru metal lines; or TaS₂ on the side and HfS₂ on the top of Ru metal lines. As an alternative to Mo, W, Ta, and Hf used in these examples, any other metal(s) listed herein, particularly a transition metal, can be used in the chalcogenides. Additional, instead of just S used in the dichalcogenides of these examples, the dichalcogenides can include Se or Te or combinations of S, Se, and/or Te. As an alternative to Ru used in the metal lines of this example, any other metal(s) listed herein may be used instead of Ru or in combination with Ru.

Various selective deposition techniques can be used to selectively grow the metal precursor layer 118 on the metal features 114 relative to the exposed surfaces 111 of substrate 110. This has the benefit that masks or other protections to protect exposed surfaces of substrate 110 are not required. For example, the metal precursor layer 118 can be deposited using any suitably selective process, such as gaseous exposure(s) of a metal-containing precursor in chemical vapor deposition (CVD) or atomic layer deposition (ALD), certain types of physical vapor deposition (PVD) (including angled PVD), or using inhibitors molecules or using selective etches, for example. Using such processes, the selective formation of the metal precursor layer 118 results at least in part from delayed or substantially slower rate of metal deposition on the exposed substrate surfaces 111 and a faster rate of metal precursor layer 118 deposition on the raised metal features 114.

Still referring to FIG. 1C, the metal precursor layer 118 may have a metal composition that includes one or more metals. In some examples, the metal(s) may include one or more transition metals. For example, the metal precursor layer 118 can include one or more of the following metals: copper (Cu), cobalt (Co), ruthenium (Ru), molybdenum (Mo), tungsten (W), nickel (Ni), hafnium (Hf), aluminum (Al), Scandium (Sc), Titanium (Ti), Vanadium (V), Manganese (Mn), Cobalt (Co), Nickel (Ni), Zinc (Zn), Yttrium (Y), Zirconium (Zr), Niobium (Nb), Technetium (Tc), Rhodium (Rh), Palladium (Pd), Silver (Ag), Tantalum (Ta), Rhenium (Re), Osmium (Os), Iridium (Ir), Platinum (Pt), Gold (Au), or combinations thereof. Alloys of such metals may be used. For example, metal precursor layer 118 can include a NiAl alloy, and/or a CuAl alloy. In some embodiments, the metal precursor layer 118 includes aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, or a mixture, alloy, combination, or a laminate thereof. In some embodiments, the metal precursor layer 118 includes W, Mo, or Ta, or a combination thereof. In another example, the metal precursor layer 118 includes any suitable transition metal(s).

Metal precursor layer 118 can have the same or a different metal composition than the metal features 114. Even when the metal compositions are the same, the use of the metal precursor layer 118 and the interface between the metal precursor layer 118 and the underlying metal features 114 helps to allow more controlled conversion of metal precursor layer 118 into a barrier layer with a 2D monolayer structure comprising one or more monolayers of 2D material. In examples in which the metal compositions are the same (or even when the compositions are different), the metal precursor layer 118 can have a different crystallinity than the metal features 114. The crystallinity difference can help to control the reaction of the metal precursor layer 118 with one or more reactant gases (described below with respect to FIG. 1D) so that the 2D material is at least substantially formed only from reaction of the metal precursor layer 118 and not unduly from a reaction of the underlying metal features 114. Thus, raised metal features 114 are less likely to be disturbed and/or the width/height reduced by the reaction described with respect to FIG. 1D. Alternatively, the metal precursor layer 118 can have a same or similar crystallinity as the metal features 114.

In other modes of practice, the metal composition of the metal precursor layer 118 is different than the metal composition of the metal features 114. This composition difference, optionally in combination with a crystalline difference between metal features 114 and metal precursor layer 118, is another way to help control the formation of the 2D monolayer material. The reaction of the metal precursor layer 118 with the reactant gases (described below with respect to FIG. 1D) may be tailored such that the 2D material is at least substantially only formed from reaction of the metal precursor layer 118 and not from reaction of the underlying metal features 114. Thus, the raised metal features 114 are less likely to be disturbed or the width/height reduced.

Using the precursor strategy thus helps to protect the valuable volume of the metal features 114, avoiding undue conversion of the metal features into chalcogenide and the associated undue loss of electrically conductive metal. Avoiding such loss means that the electrical performance of the resulting device would be more protected than other methods that do not use the precursor strategy.

Also, when different compositions are used, and because the one or more metals in the metal precursor layer 118 are converted into (e.g., semiconductor) chalcogenide material as described below, the metal composition of the metal precursor layer 118 can be customized and selected to provide chalcogenides with desired barrier and electrical properties. If barrier formation is attempted by direct chalcogenization of metal features themselves, the resultant chalcogenide is limited to being only a chalcogenide of the metal present in the metal features and the beneficial interface to control barrier formation would be absent. As discussed herein, direct chalcogenization (without a precursor step) may also unduly consume a portion of the metal features 114, which can unduly increase the overall resistivity of the metal features 114.

The metal precursor layer 118 desirably has a thickness suitable for conversion into an ultrathin barrier layer 120 of FIG. 1D, particularly conversion into a chalcogenide monolayer with a 2D structure. In some examples, a thickness of the metal precursor layer 118 can be of a thickness in the range from about 1 nm to about 10 nm, from about 1 nm to about 5 nm, or from about 1 nm to about 2 nm. Thinner layers are more preferred to form barrier layers with a 2D monolayer structure.

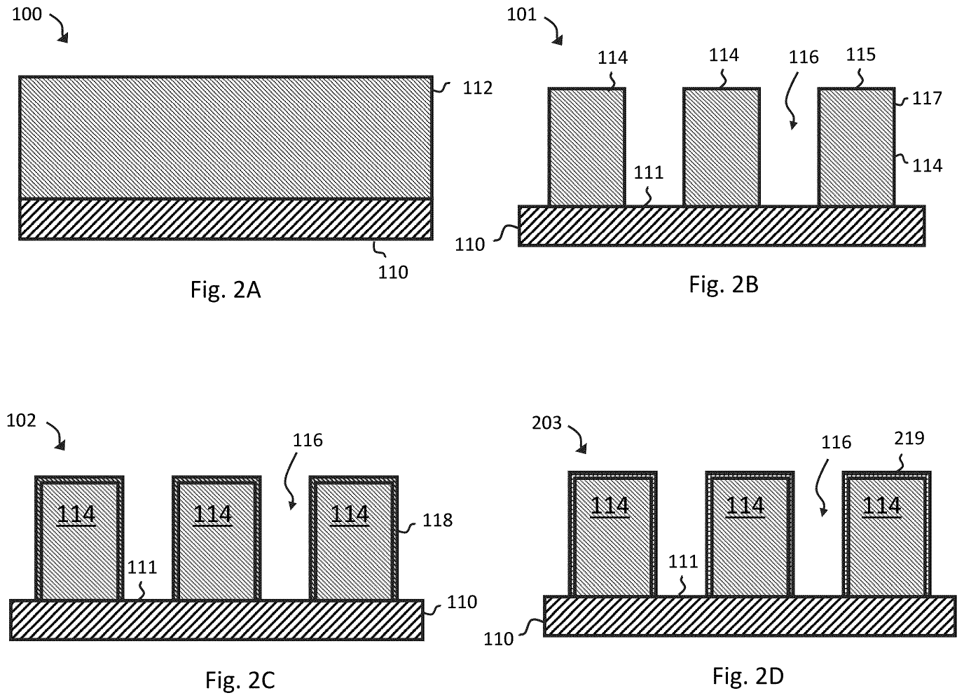

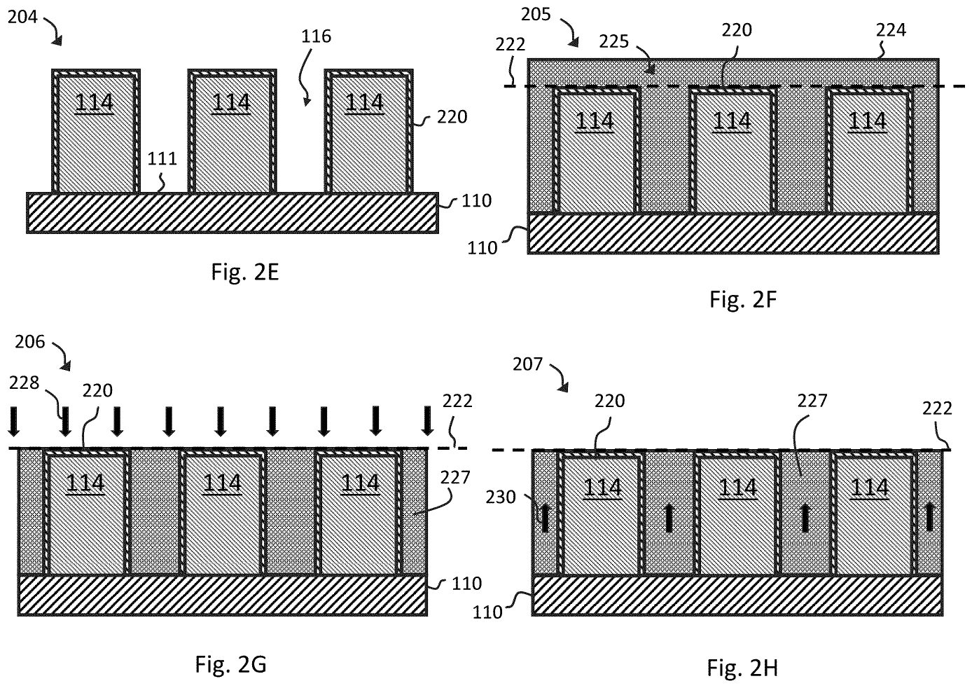

As shown schematically in FIG. 1D, the method further includes a step that comprises converting the metal precursor layer 118 of structure 102 (FIG. 1C) into the structure 103 of FIG. 1D having a barrier layer 120 comprising at least one metal chalcogenide, preferably a transition metal dichalcogenide. Advantageously, 2D monolayers may tend to have relatively high diffusion energy, which provides barrier properties inasmuch as other materials have difficulty interacting with the 2D metal chalcogenide monolayers. The step sequence of carrying out the method step of FIG. 1C followed by the method step of FIG. 1D illustrates a single stage conversion of the metal precursor layer 118 into the barrier layer 120. FIGS. 2A through 2H described below describe a two-stage conversion of a metal precursor layer 118 into the desired barrier material. The first stage of the conversion can change the surface energy of the metal precursor layer 118, which in turn can help to provide faster and/or denser formation of the 2D material in the second stage of the conversion.

Generally, the method step of FIG. 1D includes chalcogenizing the one or more metals in the metal precursor layer 118 to form one or more chalcogenides, preferably in a manner effective to form one or more monolayers of 2D chalcogenide material. An example chalcogenization and conversion desirably forms a dichalcogenide with a 2D monolayer structure. Without wishing to be bound, it is believed that every metal in such a monolayer is bonded to two chalcogens, e.g., such as for a transition metal dichalcogenide (TMD).

In the practice of the present invention, a chalcogenide is a sulfide, selenide, and/or telluride of the one or more metals in the metal precursor layer 118. In some embodiments, the resultant chalcogenide material(s), preferably 2D material, include one or more dichalcogenides of the formula MX₂, wherein M is a metal and X is one or more of S, Se, and/or Te. For example, if M is selected from one or more of aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, then corresponding sulfur, selenium and tellurium dichalcogenides include aluminum disulfide, aluminum diselenide, aluminum ditelluride, ruthenium disulfide, ruthenium diselenide, ruthenium ditelluride, molybdenum disulfide, molybdenum diselenide, molybdenum ditelluride, tungsten disulfide, tungsten diselenide, tungsten ditelluride, copper disulfide, copper diselenide, copper ditelluride, cobalt disulfide, cobalt diselenide, cobalt ditelluride, tantalum disulfide, tantalum diselenide, tantalum ditelluride, titanium disulfide, titanium diselenide, titanium ditelluride, hafnium disulfide, hafnium diselenide, and hafnium ditelluride.

The reaction to convert the metal precursor layer 118 into the barrier layer 120 generally involves reacting the metal precursor layer 118 with at least one chalcogen-containing reactant (e.g., a gas or plasma) under conditions effective to form the chalcogenide product, preferably with a 2D monolayer structure. The reactant may include elemental forms of S, Se, and/or Te, and/or gas or plasma compounds of S, Se, and/or Te. Exemplary compounds include compounds of the formula R₂-Xₘ, or R-XH, wherein each R independently is an organic substituent such as an alkyl moiety that includes 1 to 5, preferably 1 to 3, more preferably 1 to 2 carbon atoms, m is 1 or 2, and each X independently is S, Se, and/or Te. For example, illustrative gas compounds of sulfur include one or more of H₂S, SO₂, (CH₃)₂S, (CH₃)₂S₂, (CH₃CH₂)₂S, or (CH₃CH₂)₂S₂, CH₃SH, and/or CH₃CH₂SH, or the like. In addition to the reactant, the reaction environment can further contain other gas or plasma material such as a dilution gas, a reducing gas, an oxidizing gas (described below), a nitriding gas (described below) or a combination thereof.

The oxidizing, reducing, or nitriding gases may not be present at the same time as any chalcogens used in barrier layer 120 formation. The oxidizing, reducing, or nitriding gases are preferably used for pre-treatment or surface modification before chalcogenization. Such optional surface treatment can beneficially lower an energy of formation. This would allow different kinds of barrier compositions to be provided on different surfaces of the metallization. This allows selective surface modification, such as, e.g., pre-treating only a sidewall, trench bottom, or top surface of the precursor layer 118, and then proceeding to chalcogenization of the selectively pre-treated area to form 2D monolayers.

The reaction may consume the entire metal precursor layer 118 or only a portion of a thickness of the metal precursor layer 118. Consuming only a portion of the metal precursor layer 118 advantageously helps to avoid undue conversion, and hence loss, of the underlying metal features 114.

The reaction of the reactant material with the metal precursor layer 118 may be self-limiting and the reaction may stop when a monolayer of the 2D material is formed, or, if the metal precursor layer 118 is thick enough, a stack of two or more 2D monolayers. If precursor layer 118 is thick enough, a stack comprising two or more monolayers may form. During barrier layer 120 2D monolayer formation, precursor layer 118 thickness can influence monolayer formation, including the number of monolayers formed from the chalcogenization of the precursor layer 118. Additionally, process tuning and/or control can be used to control conversion of the precursor layer 118 and resulting barrier layer 120 2D monolayer formation. Alternatively, the progress of the reaction may be monitored and controllably stopped when the desired conversion is achieved. For example, such chalcogenization can be halted once a desired number or thickness of 2D monolayers have been formed on the underlying metal features 114. In self-limiting or controlled reaction strategies, the use of the metal precursor layer 118 enhances the ability to limit the reaction to the metal precursor layer 118 while protecting the underling metal features 114.

In an illustrative reaction strategy, 2D formation is achieved by reacting the metal precursor layer 118 with one or more chalcogen containing gas reactants using relatively low temperature plasma processes in which the reactant gas is excited in the gas phase and then reacts with the precursor metal layer 118 in the excited state. Excitation methods that may be used include plasma excitation, ultraviolet (UV) excitation, electron-beam (e-beam) excitation, ion-beam excitation, and hot filament excitation where the reactant gas is flowed near a hot filament. Examples of plasma sources that may be used include microwave sources, VHF-plasma sources, inductively coupled plasma (ICP) sources or capacitively coupled plasma (CCP) sources in a process chamber of a plasma processing system. According to other embodiments, plasma excitation of the reactant gas may be omitted.

A wide range of reaction temperatures would be suitable to carry out the chalcogenizing step of FIG. 1D in a manner effective to form chalcogenide material, including those with 2D monolayer structures. In some modes of practice, reaction temperatures may be in the range from about 100° C. to about 800° C. In some embodiments, the reaction temperature is in a range from 400° C. to 800° C. In other embodiments, the reaction temperature is in the range from 200° C. to 400° C. In some embodiments, the reaction temperature is in a range from 100° C. to 200° C. In some embodiments, the reaction temperature is 100° C. or even lower.

In one example, a plurality of 2D material layers may be formed by either a single set of the steps of FIGS. 1C and 1D, or by repeating the steps of FIGS. 1C and 1D, to thereby provide a stack of 2D monolayers. When such a stack is formed, the step of FIG. 1D can further include the method to remove one or more monolayers of the 2D material, such as by using an etch-back process, to remove one or more layers of the 2D material until a desired thickness of the remaining 2D material is achieved. The desired thickness can include, for example, one, two, three, or more monolayers of the 2D material such as up to 8 monolayers, up to 10 monolayers, up to 20 monolayers or even up to 35 or more monolayers. Forming an excess of monolayers and then removing some allows barrier layers 120 with a precise number of monolayers, and hence thickness, to be formed on a metal feature, among metal features in the same device, and from device to device for exceptional uniformity in performance throughout a family of devices.

A suitable thickness of barrier layer 120 may be in a range from about 3 Angstroms to about 10 nm (100 Angstroms), or about 3 Angstroms to about 5 nm, or about 3 Angstroms to about 2 nm, or about 3 Angstroms to about 1 nm. When formed from one or more 2D monolayers, the resultant barrier layer 120 desirably has a thickness equivalent to one monolayer or a stack of two or more 2D monolayers. For example, barrier layer 120 may include at least one monolayer up to a number of monolayers that avoids unduly limiting the width and/or height of the underlying metal features 114. In some examples, a stack of 2D monolayers may include 1 to 35 monolayers, 1 to 20 monolayers 1 to 10 monolayers, 1 to 5 monolayers, 1 to 3 monolayers, 1 to 2 monolayers, or even 1 monolayer in final form.

In addition to protecting against inelastic scattering and diffusion, the resulting 2D barrier layer 120 has many other benefits for metallization. For example, such 2D monolayer materials may have inherent flexibility and lack undue dangling bonds. They also are only weakly attached vertically through Van der Waals bonds, making selectively removing layers practical (see FIG. 2E, below). This allows discrete monolayers to be removed from a stack of monolayers to achieve a final barrier layer 120 with a precise number of monolayer(s) having a precisely controlled thickness that is highly uniform within a feature, among features in the device, and from device to device.

Once structure 103 of FIG. 1D is formed, the barrier layer 120 can be evaluated to determine the characteristics of the 2D monolayer structure. Different techniques may be used to evaluate the characteristics of a 2D monolayer structure. 2D monolayer structures are associated with distinctive optical emissions and other spectroscopy-related properties. Hence, spectroscopy techniques can determine or confirm the existence of 2D monolayers, a number of monolayers, a composition of the monolayers, a thickness of the monolayers individually or collectively, and the like.

For example, atomic force microscopy (AFM), scanning tunneling microscopy (STM), and transmission electron microscopy (TEM) can reveal structural properties such as surface roughness, height, defects, and lattice structure of 2D-TMDs with atomic resolution. Sec Kim, Youngbum and Kim, Jeongyong. “Near-field optical imaging and spectroscopy of 2D-TMDs” Nanophotonics, vol. 10, no. 13, 2021, pp. 3397-3415, https://doi.org/10.1515/nanoph-2021-0383; H. Li, G. Lu, Z. Yin, et al., “Optical identification of single- and few-layer MoS₂ sheets,” Small, vol. 8, pp. 682-686, 2012. https://doi.org/10.1002/smll.201101958; R. Addou, L. Colombo, and R. M. Wallace, “Surface defects on natural MoS2,” ACS Appl. Mater. Interfaces, vol. 7, pp. 11921-11929, 2015. https://doi.org/10.1021/acsami.5b01778; and L. Fei, S. Lei, and W. B. Zhang, “Direct TEM observations of growth mechanisms of two-dimensional MoS2 flakes,” Nat. Commun., vol. 7, p. 12206, 2016. https://doi.org/10.1038/ncomms12206. Also, near-field scanning microscopy (NSOM), tip-enhanced PL (TEPL), and Raman spectroscopy (TERS) techniques have been used in obtaining nanoscale optical images of 2D-TMDs. Sec Y. Lee, S. Park, H. Kim, et al., “Characterization of the structural defects in CVD-grown monolayered MoS2 using near-field photoluminescence imaging,” Nanoscale, vol. 7, pp. 11909-11914, 2015. https://doi.org/10.1039/c5nr02897c; C. Lee, B. G. Jeong, S. J. Yun, Y. H. Lee, S. M. Lee, and M. S. Jeong, “Unveiling defect-related Raman mode of monolayer WS2 via tip-enhanced resonance Raman scattering,” ACS Nano, vol. 12, pp. 9982-9990, 2018, https://doi.org/10.1021/acsnano.8b04265; and K. D. Park, T. Jiang, G. Clark, X. Xu, and M. B. Raschke, “Radiative control of dark excitons at room temperature by nano-optical antenna-tip Purcell effect,” Nat. Nanotechnol., vol. 13, pp. 59-64, 2018. https://doi.org/10.1038/s41565-017-0003-0.

As shown schematically in FIG. 1E, the method optionally further includes a step that comprises depositing a blanket dielectric layer 124 on structure 103 of FIG. 1D to thereby provide the structure 104. The dielectric layer 124 fills the voids 116 of FIG. 1D and desirably is formed with an overburden 125. The overburden 125 is shown as being the dielectric material of dielectric layer 124 above feature height line 122. The barrier-protected metal features 114 thus are buried within the blanket dielectric layer 124 at this step. Although not shown, utilizing an air gap in place of at least some of the dielectric layer 124 and related steps is also contemplated. In various embodiments, utilizing the air gap alternative can include partially filling the voids 116 with the dielectric layer 124, where non-conformal deposition (e.g., sputter deposition) results in a formation of a keyhole (void) between adjacent metal features 114. The presence of the air gap reduces the dielectric constant of the fill since air has a dielectric constant of 1, which is much lower than low-k materials.

As shown schematically in FIG. 1F, the step of FIG. 1E optionally is followed by a method step that comprises removing overburden 125 from structure 104 to feature height line 122 to expose at least a portion of the tops of the barrier-protected metal features 114. This provides the structure 105 with reduced dielectric layer 127. In an example, this step comprises performing a planarization, etching, and/or other reductive process 128 to remove dielectric overburden 125, leaving the reduced dielectric layer 127. Selective etching can be carried out that strongly favors removal of dielectric material relative to the chalcogenide material of barrier layer 120. Thus, the barrier layers 120 and the barrier-protected metal features 114 are less likely to be disturbed or to have their thickness be unduly reduced.

FIGS. 1E and 1F show a two-step sequence for converting structure 103 of FIG. 1D into structure 105 of FIG. 1F that includes the dielectric material 124. FIG. 1G schematically shows an alternative scheme to accomplish converting structure 103 of FIG. 1D into the structure 106 of FIG. 1G as an alternative to the steps of FIGS. 1E and 1F.

As shown schematically in FIG. 1G, after the method step shown schematically in FIG. 1D, the method optionally further comprises depositing a dielectric material 127 in a bottom-up deposition 130 to fill the voids 116 (FIG. 1D) to thereby form structure 106. The bottom-up deposition 130 can be practiced using strategies that deposit dielectric material 127 by delayed or relatively slower dielectric deposition on the 2D material of the barrier layer 120 and at a faster rate of dielectric deposition on the exposed surfaces 111 of the substrate 110 and as well as selectively on the deposited dielectric material 127 as its thickness builds between the barrier-protected metal features 114. The bottom-up dielectric deposition 130 may be carried out until the voids 116 are filled to a desired degree such as fully filled with the dielectric material 127 up to feature height line 122.

After completing steps shown in FIG. 1E-IF or FIG. 1G, as the case may be, the resultant structure 105 or 106, as the case may be, can be subjected to further processing, fabrication steps, or other handling as desired such as to proceed with further steps of fabrication. FIG. 1H shows an example of an optional further step of fabrication with respect to converting structure 105 of FIG. 1F into structure 107 of FIG. 1H. Structure 107 shows the result of an additional selective deposit of one or more features composed of another material 121 (e.g., a dielectric material) on the exposed surfaces of the dielectric layer 127 and preferably substantially not over the barrier layer 120 portions associated with the metal features 114. Deposition of the material 121 can be guided, prevented, or delayed on the barrier 120 due at least in part to the difference in properties between the barrier layer 120 relative to the dielectric layer 127.

The additional material 121 is helpful to selectively deposit a layer on the underlying dielectric material using the 2D material for inhibition. For example, selective deposition of a dielectric material on an underlying dielectric material can be used to help guide upper metallization to form features such as a self-aligned via. For example, feature 121 may be selectively deposited layer on the dielectric layer 127 relative to the barrier layer 120 using the 2D barrier layer 120 as a deposition boundary and for inhibition. Selectively providing dielectric material 121 on the underlying dielectric layer 127 can be used to guide various upper metals steps, such as to perform so-called “fully self-aligned via” steps.

According to an alternative embodiment of the present invention, FIGS. 2A through 2H schematically show through cross-sectional views a method of forming an ultrathin chalcogenide barrier in the metallization of a semiconductor device. Each of the Figures shows the device as a workpiece in a stage of manufacture to achieve the metallization. The method of FIGS. 2A through 2H is described with respect to forming such a chalcogenide barrier, preferably in a form including one or more monolayers of 2D chalcogenide material, as a barrier layer for raised, metal features in a semiconductor device. Advantageously, the presence of the barrier layers, particularly those that include one or more monolayers of 2D material in preferred embodiments, can reduce inelastic surface scattering and may be able to replace conventional metal and metal nitride barrier and liner layers.

The method of FIGS. 2A to 2H is identical to the method of FIGS. 1A to 1H except that a two-stage conversion strategy shown in FIGS. 2D and 2E is used to convert the precursor layer 118 of FIG. 2C into the desired barrier layer 220 of FIG. 2E instead of a single-stage conversion.

FIGS. 2A, 2B, and 2C schematically show method steps that are identical to the steps shown in FIGS. 1A, 1B, and 1C, respectively. The discussion above applicable to FIGS. 1A, 1B, and 1C applies in the same manner to FIGS. 2A, 2B, and 2C, respectively.

FIG. 2D schematically shows the step of converting the structure 102 of FIG. 2C into the structure 203 of FIG. 2D. The conversion comprises modifying at least a surface of the metal precursor layer 118 to provide modified metal precursor layer 219 as an intermediate reaction product. The result of the modification shown in FIG. 2D is to provide structure 203 including the modified precursor layer 219. The surface modification advantageously can change the surface energy of the modified metal precursor layer 119 relative to the metal precursor layer 118, which in turn can provide faster and/or denser formation of the 2D material from the modified metal precursor layer 219 in the next stage of conversion.

Such modifications to provide the modified metal precursor layer 219 may comprise reducing, oxidizing, or nitridizing at least the surface of the metal precursor layer 118. This modification will tend to convert at least a portion of the metals in the metal precursor layer 118 into oxides and/or nitrides. This can be accomplished by exposing the metal precursor layer 118 to a reducing gas, oxygen-containing gas, a nitrogen-containing gas, or both an oxygen-containing gas and a nitrogen-containing gas under conditions effective to form the oxide modification and/or nitride modification, or other desired modification.

As shown schematically in FIG. 2E, the method further includes a step that comprises converting structure 203 into structure 204. This comprises converting the modified metal precursor layer 219 into a barrier layer 220 comprising at least one chalcogenide. The method step of FIG. 2E is carried out in the same manner as described above with respect to the conversion step described with respect to FIG. 1D, and all the description and features of the step of FIG. 1D apply to FIG. 2E except that modified metal precursor layer 219 is converted into barrier layer 220 instead of metal precursor layer 118 being converted into barrier layer 120.

Generally, the method step of FIG. 2E includes chalcogenizing one or more metals in the modified metal precursor layer 219 to form barrier layer 220 including one or more chalcogenides. Preferably this conversion occurs in a manner effective to form a monolayer of 2D chalcogenide material as a constituent of barrier layer 220. A chalcogenide is a sulfide, selenide, and/or telluride of the one or more metals in the modified metal precursor layer 219. In some embodiments, the resultant chalcogenide material(s), preferably 2D material, include one or more dichalcogenides of the formula MX₂, wherein M is a metal and X is one or more of S, Se, and/or Te. For example, if M is selected from one or more of aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, then corresponding sulfur, selenium and tellurium dichalcogenides include aluminum disulfide, aluminum diselenide, aluminum ditelluride, ruthenium disulfide, ruthenium diselenide, ruthenium ditelluride, molybdenum disulfide, molybdenum diselenide, molybdenum ditelluride, tungsten disulfide, tungsten diselenide, tungsten ditelluride, copper disulfide, copper diselenide, copper ditelluride, cobalt disulfide, cobalt diselenide, cobalt ditelluride, tantalum disulfide, tantalum diselenide, tantalum ditelluride, titanium disulfide, titanium diselenide, titanium ditelluride, hafnium disulfide, hafnium diselenide, and hafnium ditelluride.

The reaction to convert the modified metal precursor layer 219 into the barrier layer 220 generally involves reacting the modified metal precursor layer 219 with at least one chalcogen-containing reactant, e.g., a gas or plasma, under conditions effective to form the chalcogenide product preferably with a 2D monolayer structure. The reactant may include elemental forms of S, Se, and/or Te, and/or compounds of S, Se, and/or Te. Exemplary gas compounds include compounds of the formula Rₘ-X_{q} or R′-XH, wherein each of R and R′ is H or an organic substituent such as an alkyl moiety that includes 1 to 3, preferably 1 to 2 carbon atoms, m is 1 or 2, and n is 1 or 2, and each X independently is S, Se, and/or Te. For example, gas compounds of sulfur include one or more of H₂S, SO₂, (CH₃)₂S, (CH₃)₂S₂, (CH₃CH₂)₂S, or (CH₃CH₂)₂S₂, CH₃SH, and/or CH₃CH₂SH, or the like. In addition to the reactants, the reaction environment can further contain additional gas or plasma, such as a dilution gas, a reducing gas, an oxidizing gas (described below), a nitriding gas (described below) or a combination thereof. Oxidation, nitridation, and reduction preferably occur as a pre-treatment prior to chalcogenization.

The reaction may consume the entire modified metal precursor layer 219 or only a portion of a thickness of the modified metal precursor layer 219. Consuming only a portion of the modified metal precursor layer 219 advantageously helps to avoid undue conversion, and hence loss, of the underlying metal features 114.

The reaction of the reactant gas with the modified metal precursor layer 219 may be self-limiting and the reaction may stop when a monolayer of the 2D material is formed or, if the metal precursor layer 219 is thick enough, a stack of two or more 2D monolayers. Alternatively, the progress of the reaction may be monitored and controllably stopped when the desired conversion is achieved. For example, such chalcogenization can be halted once a desired number or thickness of 2D monolayers have been formed on the underlying metal features 114. In self-limiting or controlled reaction strategies, the use of the modified metal precursor layer 219 enhances the ability to limit the reaction to the modified metal precursor layer 219 while protecting the underling metal features 114.

In an illustrative reaction strategy, 2D formation is achieved by reacting the metal precursor layer 118 with one or more chalcogen containing gas reactants using relatively low temperature plasma processes in which the reactant gas is excited in the gas phase and then reacts with the modified metal precursor layer 219 in the excited state. Excitation methods that may be used include plasma excitation, UV excitation, electron-beam (e-beam) excitation, ion-beam excitation, and hot filament excitation where the reactant gas is flowed near a hot filament. Examples of plasma sources that may be used include microwave sources, VHF-plasma sources, inductively coupled plasma (ICP) sources or capacitively coupled plasma (CCP) sources in a process chamber of a plasma processing system. According to other embodiments, plasma excitation of the reactant gas may be omitted.

A wide range of reaction temperatures would be suitable to carry out the chalcogenizing step of FIG. 2E in a manner effective to form chalcogenide material, including 2D monolayer structures. In some modes of practice, reaction temperatures may be in the range from about 100° C. to about 800° C. In some embodiments, the reaction temperature is in a range from 400° C. to 800° C. In other embodiments, the reaction temperature is in the range from 200° C. to 400° C. In some embodiments, the reaction temperature is in a range from 100° C. to 200° C. In some embodiments, the reaction temperature is 100° C. or even lower.

In one example, a plurality of 2D material layers may be formed by either a single set of the steps of FIGS. 2C through 2E, or by repeating the steps of FIGS. 2C through 2E to thereby provide a stack of 2D monolayers. When such a stack is formed, the step of FIG. 2E can further include the method to remove one or more monolayers of the 2D material, such as by using an etch-back process, to remove one or more layers of the 2D material until a desired thickness of the remaining 2D material is achieved. The desired thickness can include, for example, one, two, three, or more monolayers of the 2D material such as up to 8 monolayers, up to 10 monolayers, up to 20 monolayers or even up to 35 or more monolayers. Forming an excess of monolayers and then removing some allows barrier layers 120 with a precise number of monolayers, and hence thickness, to be formed on a metal feature, among metal features in the same device, and from device to device for exceptional uniformity in performance throughout a family of devices.

A suitable thickness of barrier layer 220 may be in a range from about 3 Angstroms to about 10 nm (100 Angstroms), or about 3 Angstroms to about 5 nm, or about 3 Angstroms to about 2 nm, or about 3 Angstroms to about 1 nm. When formed from one or more 2D monolayers, the resultant barrier layer 220 desirably has a thickness equivalent to one monolayer or a stack of two or more 2D monolayers. For example, barrier layer 220 may include at least one monolayer up to a number of monolayers that avoids unduly limiting the width and/or height of the underlying metal features 114. In some examples, a stack of 2D monolayers may include 1 to 35 monolayers, 1 to 20 monolayers 1 to 10 monolayers, 1 to 5 monolayers, 1 to 3 monolayers, 1 to 2 monolayers, or even 1 monolayer in final form.

In addition to protect against inelastic scattering and diffusion, the resulting 2D barrier layer 220 has other benefits for metallization. For example, such 2D monolayer materials have inherent flexibility and lack undue dangling bonds. They also are only weakly attached vertically through Van der Waals bonds, making selectively removing layers practical. This allows discrete monolayers to be removed from a stack of monolayers to achieve a final barrier layer 220 with a precise number of monolayer(s) having a precisely controlled thickness that is highly uniform within a feature, among features in the device, and from device to device.

As shown schematically in FIG. 2F, the method optionally further includes a step that comprises depositing a blanket dielectric layer 224 on structure 204 of FIG. 2E to thereby provide the structure 205 of FIG. 2F. The dielectric layer 224 fills the voids 116 of FIG. 2E and desirably is formed with an overburden 225 above feature height line 222. The barrier-protected metal features 114 thus are buried within the dielectric layer 224 at this step.

As shown schematically in FIG. 2G, the step of FIG. 2F is followed by a method step that comprises removing overburden 225 from structure 205 to feature height line 222 to expose at least a portion of the tops of the barrier-protected metal features 114. This provides the structure 206. In an example, this step comprises performing a planarization, etching, and/or other reductive process 228 to remove overburden 225. Selective etching can be carried out that strongly favors removal of dielectric material relative to the chalcogenide material of barrier layer 220. Thus, the barrier layers 220 and the barrier-protected metal features 114 are less likely to be disturbed or to have their thickness be unduly reduced.

FIGS. 2F and 2G show a two-step sequence for converting structure 204 of FIG. 2E into structure 206 of FIG. 2G that includes the dielectric material 224. FIG. 2H schematically shows an alternative scheme to accomplish converting structure 204 of FIG. 2E into the structure 207 of FIG. 1G as an alternative to the steps of FIGS. 2F and 2G.

As shown schematically in FIG. 2H, after the method step shown schematically in FIG. 2E, the method further comprises depositing a dielectric material 227 in a bottom-up deposition 230 to fill the voids 116 (FIG. 2E) in the metal features 114 to thereby form structure 207. The bottom-up deposition 230 can be practiced using strategies that deposit dielectric material 227 by delayed or relatively slower dielectric deposition on the 2D material of the barrier layer 220 and at a faster rate of dielectric deposition on the exposed surfaces 111 (see FIG. 2E) of the substrate 110 and as well as selectively on the deposited dielectric material 227 as its thickness builds between the barrier-protected metal features 114. The bottom-up dielectric deposition 230 may be carried out until the voids 116 are filled to a desired degree such as being fully filled with the dielectric material 227 up to feature height line 222.

After FIG. 2G or FIG. 2H, as the case may be, the resultant structure 206 or 207, as the case may be, can be subjected to further processing, fabrication steps, or other handling as desired such as to proceed with further steps of fabrication. As an example, either structure 206 or 207 may be used in the method step of FIG. 1H in place of structures 105 or 106 to form the features 121 similar to as shown in structure 107 of FIG. 1H.

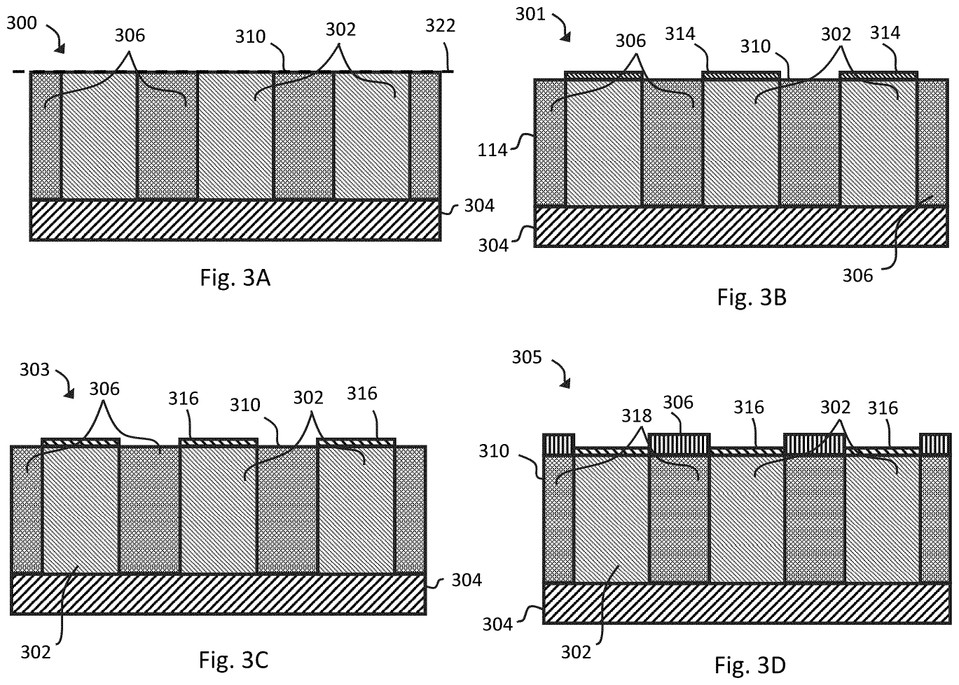

According to an illustrative embodiment of the present invention, FIGS. 3A through 3D schematically show through cross-sectional views a method of forming an ultrathin, (e.g., semiconductor) chalcogenide barrier, preferably in the form of a barrier comprising at least one 2D material-based monolayer, in the metallization of a semiconductor device at a stage of fabrication involving metallization. Specifically, the method comprises forming a capping layer in metallization of a semiconductor device according to an embodiment of the present invention. Each of the figures shows the device as a workpiece in a stage of manufacture to achieve the capped metallization.

FIG. 3A schematically shows the step of providing a semiconductor device 300 at a stage of fabrication at which metallization is occurring. Device 300 includes metal features 302 and dielectric material 306 supported on a substrate 304. In some examples, the metal features 302 include contacts and interconnects. In this example, the structure 300 may be planarized so that the metal features 302 and the dielectric material 306 are co-planar at the feature height line 322. In the context of FIG. 3A, a barrier layer (not shown) optionally may be interposed at the interfaces between the metal features 302 and the dielectric material 306. The combination of the metal features 302 and the dielectric material 306 may be formed on substrate 302 using patterning and/or damascene techniques.

FIG. 3B schematically shows a step comprising converting structure 300 of FIG. 3A into the structure 301 of FIG. 3B. This step comprises selectively forming a metal precursor cap 314 on exposed surfaces of the metal features 114 relative to the surfaces 310 of the dielectric material 306. Using a method that proceeds through metal precursor cap 314 as an intermediate makes it easier to form a resultant barrier cap 316 (FIG. 3C) that includes one or more 2D monolayers and to do so with more control and precision as compared to methods that would attempt to directly surface modify metal features 302 themselves or through direct deposition of a 2D structure onto the metal features 302.

Various selective deposition techniques can be used to selectively grow the metal precursor cap 314 on the metal features 302 relative to the exposed surfaces 310 of dielectric material 306. This has the benefit that masks or other protections to protect exposed surfaces 310 of dielectric material 306 are not required. For example, the metal precursor cap 314 can be deposited using any suitably selective process, such as gaseous exposure(s) of a metal-containing precursor in chemical vapor deposition (CVD) or atomic layer deposition (ALD), certain types of physical vapor deposition (PVD) (including angled PVD), or using inhibitors molecules or using selective etches, for example. Using such processes, the selective formation of the metal precursor cap 314 results at least in part from delayed or substantially slower rate of metal deposition on the exposed dielectric surfaces 310 and a faster rate of metal precursor cap 314 deposition on the exposed surfaces of the metal features 302.

The metal precursor cap 314 may have a metal composition that includes one or more metals. For example, the metal precursor cap 314 can include one or more of the following metals: copper (Cu), cobalt (Co), ruthenium (Ru), molybdenum (Mo), tungsten (W), nickel (Ni), hafnium (Hf), aluminum (Al), Scandium (Sc), Titanium (Ti), Vanadium (V), Manganese (Mn), Cobalt (Co), Nickel (Ni), Zinc (Zn), Yttrium (Y), Zirconium (Zr), Niobium (Nb), Technetium (Tc), Rhodium (Rh), Palladium (Pd), Silver (Ag), Tantalum (Ta), Rhenium (Re), Osmium (Os), Iridium (Ir), Platinum (Pt), Gold (Au), or combinations of these. Alloys of such metals may be used. For example, metal precursor cap 314 can include a NiAl alloy, and/or a CuAl alloy. In some embodiments, the metal precursor cap 314 includes aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, rhodium (Rh), iridium (Ir), or a mixture, alloy, combination, or a laminate thereof. In some embodiments, the metal precursor cap 314 includes W, Mo or Ta, or a combination thereof. In another example, the metal precursor cap 314 includes any transition metal(s).

Metal precursor cap 314 can have the same or a different metal composition than the metal features 302. Even when the metal compositions are the same, the presence of the metal precursor cap 314 and the interface between the metal precursor cap 314 and the underlying metal features 302 allow more controlled conversion of metal precursor cap 314 into a barrier cap 316 (FIG. 3C) with a 2D monolayer structure comprising one or more monolayers. In an example in which the metal compositions are the same (or even when the compositions are different), the metal precursor cap 314 can have a different crystallinity than the metal features 302. The crystallinity difference can help to control the reaction of the metal precursor cap 314 with one or more reactant gases (described below with respect to FIG. 3C) so that the 2D material is at least substantially formed only from reaction of the metal precursor cap 314 and not unduly from reaction of the underlying metal features 302. Thus, metal features 302 are less likely to be disturbed and/or the width/height reduced by the reaction described with respect to FIG. 3C. Alternatively, the metal precursor cap 314 can have a same or similar crystallinity than the metal features 302.

In other modes of practice, the metal composition of the metal precursor cap 314 is different than the metal composition of the metal features 302. This composition difference is another way to help control the formation of the 2D monolayer material. In this example, the reaction of the metal precursor cap 314 with the reactant gases (described below with respect to FIG. 3C) may be tailored such that the 2D material is at least substantially only formed from reaction of the metal precursor cap 314 and not from reaction of the underlying metal features 302. Thus, the metal features 302 are less likely to be disturbed or the width/height reduced. Using the precursor strategy thus helps to protect the valuable volume of the metal features 302, avoiding undue conversion of the metal features into chalcogenide and the associated undue loss of electrically conductive metal. Avoiding such loss means that the electrical performance of the resulting device would be more protected than other methods that do not use the precursor strategy.

Also, when different compositions are used, and because the one or more metals in the metal precursor cap 314 are converted into a chalcogenide material as described below, the metal composition of the metal precursor cap 314 can be customized and selected to provide chalcogenides with desired barrier and electrical properties. If barrier formation is attempted by direct chalcogenization of metal features themselves, the resultant chalcogenide is limited to being only a chalcogenide of the metal present in the metal features and the beneficial interface to control barrier formation would be absent.

The metal precursor cap 314 desirably has a thickness suitable for conversion into an ultrathin barrier layer, particularly conversion into a chalcogenide monolayer with a 2D structure. In some examples, a thickness of the metal precursor cap 314 can be a thickness in the range from about 1 nm to about 10 nm, from about 1 nm to about 5 nm, or from about 1 nm to about 2 nm. Thinner layers are more preferred to form barrier layers with a 2D monolayer structure.

As shown schematically in FIG. 3C, the method further includes a step that comprises converting the metal precursor cap 314 of structure 301 (FIG. 3B) into a barrier cap 316 of structure 303 (FIG. 3C), wherein the barrier cap 316 comprises at least one chalcogenide. The step sequence of carrying out the method step of FIG. 3B followed by the method step of FIG. 3C illustrates a single stage conversion of the metal precursor cap 314 into the barrier cap 316. metal precursor cap 314

Generally, the method step of FIG. 3C includes chalcogenizing the one or more metals in the metal precursor cap 314 to form one or more chalcogenides, preferably in a manner effective to form a monolayer of 2D chalcogenide material. In the practice of the present invention, a chalcogenide is a sulfide, selenide, and/or telluride of the one or more metals in the metal precursor cap 314. In some embodiments, the resultant chalcogenide material(s), preferably 2D material, include one or more dichalcogenides of the formula MX₂, wherein M is a metal and X is one or more of S, Se, and/or Te. For example, if M is selected from one or more of aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, then corresponding sulfur, selenium and tellurium dichalcogenides include aluminum disulfide, aluminum diselenide, aluminum ditelluride, ruthenium disulfide, ruthenium diselenide, ruthenium ditelluride, molybdenum disulfide, molybdenum diselenide, molybdenum ditelluride, tungsten disulfide, tungsten diselenide, tungsten ditelluride, copper disulfide, copper diselenide, copper ditelluride, cobalt disulfide, cobalt diselenide, cobalt ditelluride, tantalum disulfide, tantalum diselenide, tantalum ditelluride, titanium disulfide, titanium diselenide, titanium ditelluride, hafnium disulfide, hafnium diselenide, and hafnium ditelluride.

The reaction to convert the metal precursor cap 314 into the barrier cap 316 generally involves reacting the metal precursor cap 314 with at least one chalcogen-containing reactant (e.g., a gas or plasma) under conditions effective to form the chalcogenide product preferably with a 2D monolayer structure. The reactant gas may include elemental forms of S, Se, and/or Te, and/or gas or plasma compounds of S, Se, and/or Te. Exemplary gas compounds include compounds of the formula Rₘ-X_{q} or R′-XH, wherein each of R and R′ is H or an organic substituent such as an alkyl moiety that includes 1 to 3, preferably 1 to 2 carbon atoms, m is 1 or 2, and n is 1 or 2, and each X independently is S, Se, and/or Te. For example, illustrative gas compounds of sulfur include one or more of H₂S, SO₂, (CH₃)₂S, (CH₃)₂S₂, (CH₃CH₂)₂S, or (CH₃CH₂)₂S₂, CH₃SH, and/or CH₃CH₂SH, or the like. In addition to the reactant, the reaction environment can further contain other gas or plasma material such as a dilution gas, a reducing gas, an oxidizing gas (described below), a nitriding gas (described below) or a combination thereof.

The reaction may consume the entire metal precursor cap 314 or only a portion of a thickness of the metal precursor cap 314. Consuming only a portion of the metal precursor cap 314 advantageously helps to avoid undue conversion, and hence loss, of the underlying metal features 302.

The reaction of the reactant material with the metal precursor cap 314 may be self-limiting and the reaction may stop when a monolayer of the 2D material is formed, or, if the metal precursor cap 314 is thick enough, a stack of two or more 2D monolayers. Alternatively, the progress of the reaction may be monitored and controllably stopped when the desired conversion is achieved. For example, such chalcogenization can be halted once a desired number or thickness of 2D monolayers have been formed on the underlying metal features 302. In self-limiting or controlled reaction strategies, the use of the metal precursor cap 314 enhances the ability to limit the reaction to the metal precursor cap 314 while protecting the underlying metal features 302.

In an illustrative reaction strategy, 2D formation is achieved by reacting the metal precursor cap 314 with one or more chalcogen containing gas reactants using relatively low temperature plasma processes in which the reactant gas is excited in the gas phase and then reacts with the precursor metal cap 314 in the excited state. Excitation methods that may be used include plasma excitation, UV excitation, electron-beam (e-beam) excitation, ion-beam excitation, and hot filament excitation where the reactant gas is flowed near a hot filament. Examples of plasma sources that may be used include microwave sources, VHF-plasma sources, inductively coupled plasma (ICP) sources or capacitively coupled plasma (CCP) sources in a process chamber of a plasma processing system. According to other embodiments, plasma excitation of the reactant gas may be omitted.

A wide range of reaction temperatures would be suitable to carry out the chalcogenizing step of FIG. 3C in a manner effective to form chalcogenide material, including those with 2D monolayer structures. In some modes of practice, reaction temperatures may be in the range from about 100° C. to about 800° C. In some embodiments, the reaction temperature is in a range from 400° C. to 800° C. In other embodiments, the reaction temperature is in the range from 200° C. to 400° C. In some embodiments, the reaction temperature is in a range from 100° C. to 200° C. In some embodiments, the reaction temperature is 100° C. or even lower.

In one example, a plurality of 2D monolayers may be formed by either a single set of the steps of FIGS. 3B and 3C, or by repeating the steps of FIGS. 3B and 3C to thereby provide a stack of 2D monolayers. When such a stack is formed, the step of FIG. 3C can further include the method to remove one or more monolayers of the 2D material, such as by using an etch-back process, to remove one or more layers of the 2D material until a desired thickness of the remaining 2D material is achieved. The desired thickness can include, for example, one, two, three, or more monolayers of the 2D material such as up to 8 monolayers, up to 10 monolayers, up to 20 monolayers or even up to 35 or more monolayers. Forming an excess of monolayers and then removing some allows barrier layers 316 to be formed with a precise number of monolayers, and hence thickness, to be formed on a metal feature, among metal features in the same device, and from device to device for exceptional uniformity in performance throughout a family of devices.

A suitable thickness of barrier cap 316 may be in a range from about 3 Angstroms to about 10 nm (100 Angstroms), or about 3 Angstroms to about 5 nm, or about 3 Angstroms to about 2 nm, or about 3 Angstroms to about 1 nm. When formed from one or more 2D monolayers, the resultant barrier cap 316 desirably has a thickness equivalent to one monolayer or a stack of two or more 2D monolayers. For example, barrier cap 316 may include at least one monolayer up to a number of monolayers that avoids unduly limiting the width and/or height of the underlying metal features 302. In some examples, a stack of 2D monolayers may include 1 to 35 monolayers, 1 to 20 monolayers 1 to 10 monolayers, 1 to 5 monolayers, 1 to 3 monolayers, 1 to 2 monolayers, or even 1 monolayer in final form.

In addition to protect against inelastic scattering and diffusion, the resulting 2D barrier cap 316 has other benefits for metallization. For example, such 2D monolayer materials may have inherent flexibility and lack undue dangling bonds. They also are only weakly attached vertically through Van der Waals bonds, making selectively removing layers practical. This allows discrete monolayers to be removed from a stack of monolayers to achieve a final barrier cap 316 with a precise number of monolayer(s) having a precisely controlled thickness that is highly uniform within a feature, among features in the device, and from device to device.

After FIG. 3C, as the case may be, the resultant structure 303 can be subjected to further processing, fabrication steps, or other handling as desired such as to proceed with further steps of fabrication. FIG. 3D shows an example of a further step of fabrication with respect to converting structure 303 of FIG. 3C into structure 305 of FIG. 3D. Structure 305 shows the result of an additional selective deposit of another material 318 (e.g., a dielectric material) on the exposed surfaces of the dielectric material 306 and preferably not over the barrier cap 316. Deposition of the material 318 can be prevented or delayed on the barrier cap 316 due to the difference in properties between the barrier cap 316 relative to the dielectric material 306.

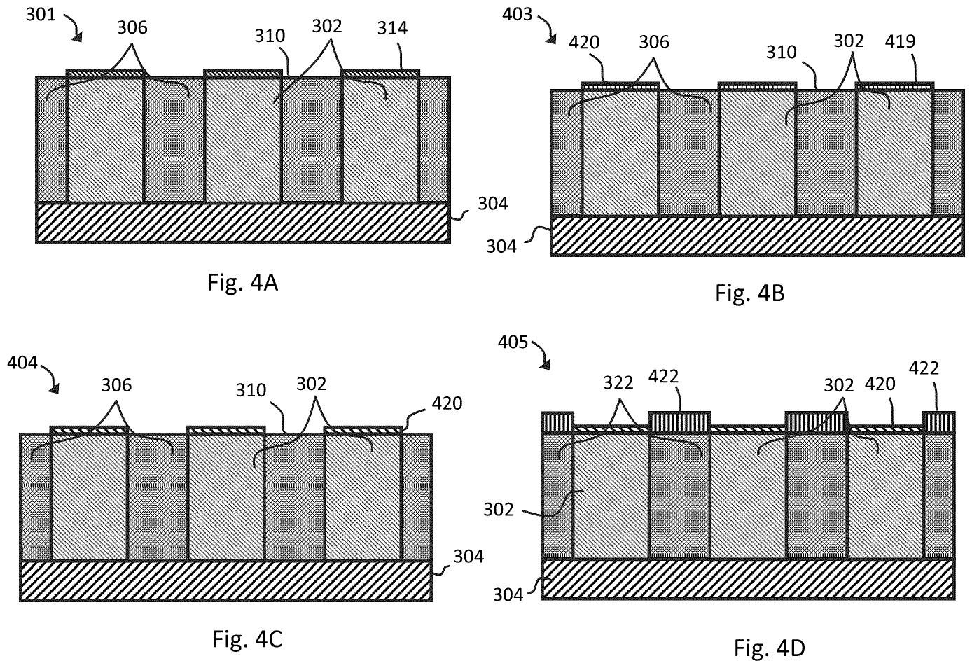

According to an illustrative embodiment of the present invention, FIGS. 4A through 4D schematically show through cross-sectional views a method of forming an ultrathin chalcogenide barrier, preferably in the form of a barrier comprising at least one 2D monolayer, in the metallization of a semiconductor device. Specifically, the method comprises forming a capping layer in metallization of a semiconductor device according to an embodiment of the present invention in which a two-stage sequence is used to convert a precursor into the desired barrier. Each of the figures shows the device as a workpiece in a stage of manufacture to achieve the capped metallization.

FIG. 4A schematically shows a step of providing a structure 301 as shown in FIG. 3B. The discussion above applicable to FIG. 3B applies in the same manner to FIG. 3B and to how the structure 301 may be obtained from the structure 300 of FIG. 3A. Following the step schematically shown in FIG. 4A, FIGS. 4B and 4C schematically show a two-stage conversion of the metal precursor cap 314 into barrier cap 420 of FIG. 4C.

FIG. 4B schematically shows the step of converting the structure 301 of FIG. 4A into the structure 403 of FIG. 4B. The conversion comprises modifying at least a surface of the metal precursor cap 314 to provide modified metal precursor cap 419 as an intermediate reaction product. The result of the modification shown in FIG. 4B is to provide structure 403 including the modified precursor cap 419. The surface modification advantageously can change the surface energy of the modified metal precursor cap 419 relative to the metal precursor cap 314, which in turn can provide faster and/or denser formation of the 2D material from the modified metal precursor cap 419 in the next stage of conversion.

Such modifications to provide the modified metal precursor cap 419 may comprise reducing, oxidizing, or nitridizing at least the surface of the metal precursor cap 314. This modification will tend to convert at least a portion of the metals in the metal precursor cap 314 into oxides and/or nitrides. This can be accomplished by exposing the metal precursor cap 314 to a reducing gas, oxygen-containing gas, a nitrogen-containing gas, or both an oxygen-containing gas and a nitrogen-containing gas under conditions effective to form the oxide modification and/or nitride modification, or other desired modification.

FIG. 4C schematically shows a method step that is identical to the method step of FIG. 3C except that the method step is practiced on the structure 403 in order to convert the modified precursor cap 419 into the desired barrier layer 420. Generally, the method step of FIG. 4C includes chalcogenizing one or more of the metals in the modified metal precursor cap layer 419 to form one or more chalcogenides, preferably in a manner effective to form a monolayer of 2D chalcogenide material(s).

In some embodiments, the resultant chalcogenide material(s) in barrier cap 420, preferably in the form of 2D monolayer material, include one or more dichalcogenides of the formula MX₂, wherein M is a metal and X is one or more of S, Se, and/or Te. For example, if M is selected from one or more of aluminum (Al), ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, then corresponding sulfur, selenium and tellurium dichalcogenides include aluminum disulfide, aluminum diselenide, aluminum ditelluride, ruthenium disulfide, ruthenium diselenide, ruthenium ditelluride, molybdenum disulfide, molybdenum diselenide, molybdenum ditelluride, tungsten disulfide, tungsten diselenide, tungsten ditelluride, copper disulfide, copper diselenide, copper ditelluride, cobalt disulfide, cobalt diselenide, cobalt ditelluride, tantalum disulfide, tantalum diselenide, tantalum ditelluride, titanium disulfide, titanium diselenide, titanium ditelluride, hafnium disulfide, hafnium diselenide, and hafnium ditelluride.

The reaction of FIG. 4C generally involves reacting the modified metal precursor cap 419 with at least one chalcogen-containing reactant (e.g., a gas or plasma) under conditions effective to form the chalcogenide product preferably with a 2D monolayer structure. The reactant may include elemental forms of S, Se, and/or Te, and/or compounds of S, Se, and/or Te. Exemplary compounds include compounds of the formula Rₘ-X_{q} or R′-XH, wherein each of R and R′ is H or an organic substituent such as an alkyl moiety that includes 1 to 3, preferably 1 to 2 carbon atoms, m is 1 or 2, and n is 1 or 2, and each X independently is S, Se, and/or Te. For example, gas compounds of sulfur include one or more of H₂S, SO₂, (CH₃)₂S, (CH₃)₂S₂, (CH₃CH₂)₂S, or (CH₃CH₂)₂S₂, CH₃SH, and/or CH₃CH₂SH, or the like. In addition to the reactants, the reaction environment can further contain other gas or plasma materials such as a dilution gas, a reducing gas, an oxidizing gas (described below), a nitriding gas (described below) or a combination thereof. Examples of oxidation, nitridation, reduction can be used in a pre-treatment for surface modification and preferably occur prior to exposing the metal precursor layer 219 to a chalcogenizing gas.

The reaction may consume the entire metal precursor cap 419 or only a portion of a thickness of the modified metal precursor cap 419. Consuming only a portion of the modified metal precursor cap 419 advantageously helps to avoid undue conversion, and hence loss, of the underlying metal features 302.

The reaction of the reactant material with the modified metal precursor cap 419 may be self-limiting and the reaction may stop when a monolayer of the 2D material is formed, or if the precursor cap 419 is thick enough, a stack comprising two or more 2D monolayers. Alternatively, the progress of the reaction may be monitored and controllably stopped when the desired conversion is achieved. For example, such chalcogenization can be halted once a desired number or thickness of 2D monolayers have been formed on the underlying metal features 302. In self-limiting or controlled reaction strategies, the use of the modified metal precursor cap 419 enhances the ability to limit the reaction to the modified metal precursor cap 419 while protecting the underlying metal features 302.

In an illustrative reaction strategy, 2D formation is achieved by reacting the modified metal precursor cap 419 with one or more chalcogen containing reactants using relatively low temperature plasma processes in which the reactant material is excited in the gas phase and then reacts with the modified precursor metal cap 419 in the excited state. Excitation methods that may be used include plasma excitation, UV excitation, electron-beam (e-beam) excitation, ion-beam excitation, and hot filament excitation where the reactant gas is flowed near a hot filament. Examples of plasma sources that may be used include microwave sources, VHF-plasma sources, inductively coupled plasma (ICP) sources or capacitively coupled plasma (CCP) sources in a process chamber of a plasma processing system. According to other embodiments, plasma excitation of the reactant gas may be omitted.

A wide range of reaction temperatures would be suitable to carry out the chalcogenizing step of FIG. 4C in a manner effective to form chalcogenide material, including forming 2D monolayer structures. In some modes of practice, reaction temperatures may be in the range from about 100° C. to about 800° C. In some embodiments, the reaction temperature is in a range from 400° C. to 800° C. In other embodiments, the reaction temperature is in the range from 200° C. to 400° C. In some embodiments, the reaction temperature is in a range from 100° C. to 200° C. In some embodiments, the reaction temperature is 100° C. or even lower.

In one example, a plurality of 2D material layers may be formed by either a single set of the steps of FIGS. 4A through 4C, or by repeating the steps of FIGS. 4A through 4C to thereby provide a stack of 2D monolayers. When such a stack is formed, the step of FIG. 4C can further include the method to remove one or more monolayers of the 2D material, such as by using an etch-back process, to remove one or more layers of the 2D material until a desired thickness of the remaining 2D material is achieved. The desired thickness can include, for example, one, two, three, or more monolayers of the 2D material such as up to 8 monolayers, up to 10 monolayers, up to 20 monolayers or even up to 35 or more monolayers. Forming an excess of monolayers and then removing some allows barrier layers 420 to be formed with a precise number of monolayers, and hence thickness, to be formed on a metal feature, among metal features in the same device, and from device to device for exceptional uniformity in performance throughout a family of devices.

A suitable thickness of barrier layer 420 may be in a range from about 3 Angstroms to about 10 nm (100 Angstroms), or about 3 Angstroms to about 5 nm, or about 3 Angstroms to about 2 nm, or about 3 Angstroms to about 1 nm. When formed from one or more 2D monolayers, the resultant barrier layer 420 desirably has a thickness equivalent to one monolayer or a stack of two or more 2D monolayers. For example, barrier layer 420 may include at least one monolayer up to a number of monolayers that avoids unduly limiting the width and/or height of the underlying metal features 114. In some examples, a stack of 2D monolayers may include 1 to 35 monolayers, 1 to 20 monolayers 1 to 10 monolayers, 1 to 5 monolayers, 1 to 3 monolayers, 1 to 2 monolayers, or even 1 monolayer in final form.

In addition to protect against inelastic scattering and diffusion, the resulting 2D barrier layer 420 has other benefits for metallization. For example, such 2D monolayer materials have inherent flexibility and lack undue dangling bonds. They also are only weakly attached vertically through Van der Waals bonds, making selectively removing layers practical. This allows discrete monolayers to be removed from a stack of monolayers to achieve a final barrier layer 420 with a precise number of monolayer(s) having a precisely controlled thickness that is highly uniform within a feature, among features in the device, and from device to device.

After completing step shown in FIG. 4C, the resultant structure 404 can be subjected to further processing, fabrication steps, or other handling as desired such as to proceed with further steps of fabrication. FIG. 4D shows an example of a further step of fabrication with respect to converting structure 404 of FIG. 4C into structure 405 of FIG. 4D. Structure 405 shows the result of an additional selective deposit of another material 422 (e.g., a dielectric material) on the exposed surfaces of the dielectric material 306 and preferably not over the barrier cap 420. Deposition of the material 422 can be prevented or delayed on the barrier cap 420 due to the difference in properties between the barrier cap 420 relative to the dielectric material 306.

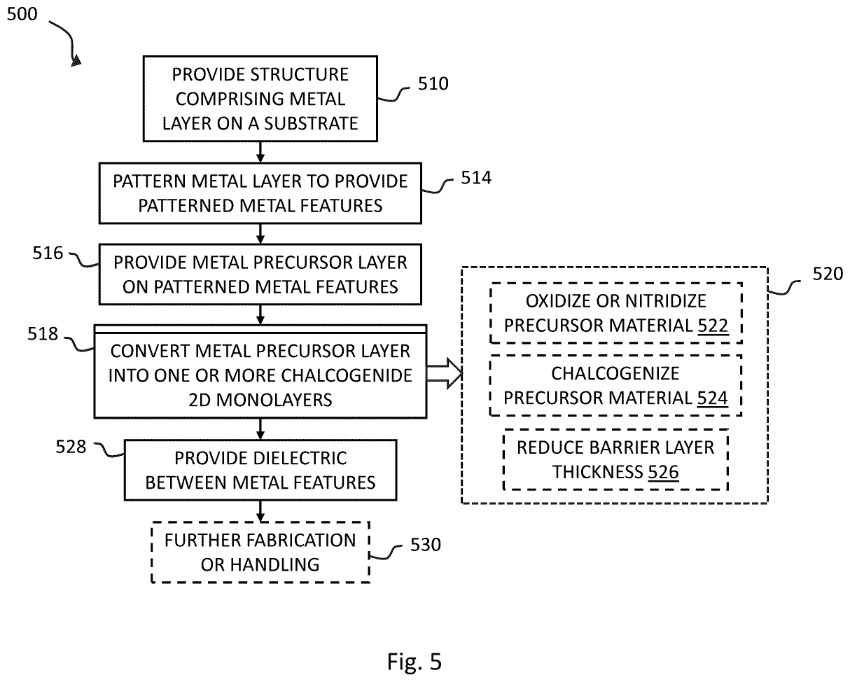

FIG. 5 is a flowchart that schematically shows a method 500 of integrating principles of the present invention into metallization strategies. Method step 510 comprises providing a structure comprising a metal layer on a substrate. Illustrative embodiments of this method step 510 are schematically illustrated and described herein with respect to FIGS. 1A and 2A.

Method step 514 comprises patterning the metal layer to provide patterned metal features. Illustrative embodiments of this method step 514 are schematically illustrated and described herein with respect to FIGS. 1B and 2B.

Method step 516 comprises providing a metal precursor layer on the patterned metal features. Illustrative embodiments of this method step 512 are schematically illustrated and described herein with respect to FIGS. 1C and 2D.

Method step 518 includes converting the metal precursor layer into one or more chalcogenide, 2D monolayers to thereby provide a barrier layer over the patterned metal features. Method step 518 may occur using a method comprising a single stage or two stages. In a single stage, step 520 shows that this conversion may occur by chalcogenizing the precursor material to form the desired barrier material. Illustrative embodiments of this single stage conversion are described herein with respect to FIGS. 1D and 3C. If a two-stage conversion is used, the conversion includes a first step of oxidizing and/or nitridizing at least a portion of the precursor material to provide modified precursor material. In a second stage, the modified precursor material is converted into a (e.g., semiconductor) chalcogenide. Illustrative embodiments of this two-stage conversion are described herein with respect to FIG. 2C to 2E and FIGS. 4A to 4C. Following other a single-stage or two-stage conversion, the barrier material optionally can be reduced in thickness to provide a barrier layer with the desired final thickness.

Step 530 shows that the metallization may be followed by further fabrication or handling.

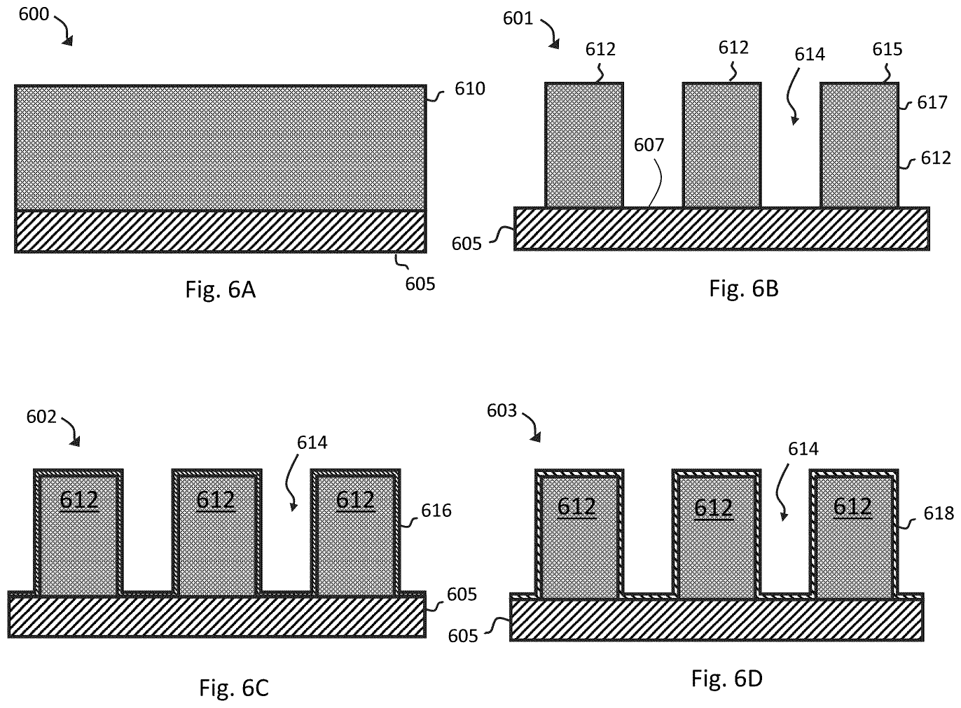

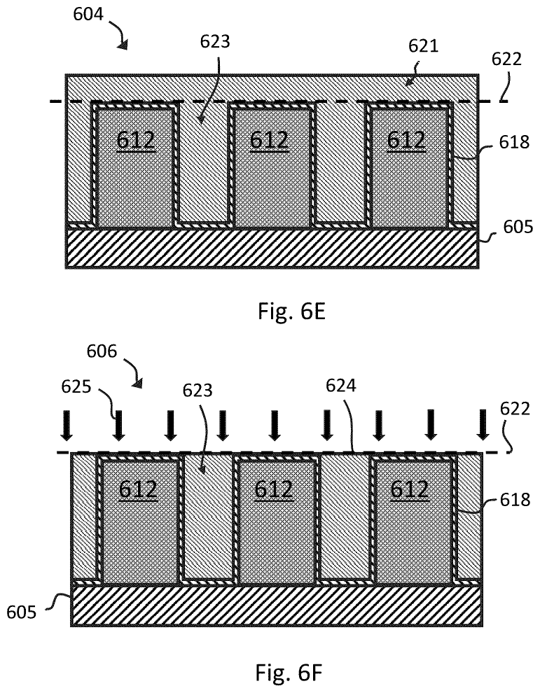

Principles of the present invention also are useful to provide barriers in metallization using damascene strategies, including single damascene, dual damascene, and semi-damascene strategies. For example, the illustrative method of FIGS. 6A through 6F is described with respect to forming ultrathin chalcogenide barriers, preferably including one or more monolayers of 2D material, in which a damascene-based process is used to carry out metallization in fabrication of a semiconductor device. Each of the figures shows the device as a workpiece in a stage of manufacture to achieve the metallization.

FIG. 6A schematically shows the step of providing an in-process microelectronic device 600. For purposes of illustration, a portion of the semiconductor device 600 is shown. The partially manufactured device 600 includes a structure containing a dielectric layer 610 on a substrate 605 whose features and characteristics are the same as those of substrate 110 of FIG. 1A. The dielectric layer 610 can, for example, include silicon dioxide and/or any low-k and/or high-k dielectric material or combinations thereof that is suitable for use in semiconductor devices. As used herein, a high-k dielectric refers to a material with a dielectric constant greater than 3.9, and a low-k dielectric material refers to a material with a dielectric constant of 3.9 or less (silicon dioxide has a dielectric constant of 3.9). Examples of dielectric materials include oxides, nitrides, and oxynitrides of one or more metals, combinations of these and the like. Exemplary metal constituents of dielectric materials include Si, Hf, Ta, Ba, Sr, Pb, Mg, Mo, Zr, Bi, combinations of these, and the like Specific examples of dielectric materials include SiO2, organic substituent containing dielectrics such as TEOS, hafnium oxides, hafnium nitrides, hafnium oxynitrides, silicon oxynitrides, nitride hafnium silicates, nanoporous silica, hydrogensilsesquioxanes, polytetrafluoroethylene, silicon oxyfluoride, silicon nitrides, tantalum oxides, tantalum nitrides, tantalum oxynitrides, barium-strontium titanates, lead magnesium niobates and other perovskite metal oxides, lead zirconium titanate, strontium bismuth tantalate, combinations of these, or any other suitable dielectric material(s).

FIG. 6B schematically shows the step of converting structure 600 of FIG. 6A into the structure 601 of FIG. 6B. This conversion comprises patterning the dielectric layer 610 to form patterned dielectric features 612 on the substrate 605. The patterning techniques used to form structure 601 may include the steps (not shown) of forming a photoresist layer over the dielectric layer 610, patterning the photoresist layer using lithography techniques to form a mask layer, using the resulting mask layer and subtractive techniques such as etching to form the patterned dielectric features 612 on the substrate 110, and then removing the mask material. The resulting dielectric features 612 contain top surfaces 615 and sidewall surfaces 617.

FIG. 6B shows voids 614 between features 612 extending all the way to the substrate 605, but some voids (not shown) may be shallower, extending only partially into the depth of the patterned dielectric material features 612. Voids 614 in some modes of practice may correspond to vias and trenches in which contacts (not shown) and interconnects (not shown), respectively, subsequently may be formed by filling the voids 614 with electrically conductive metal material as described below.

As schematically shown in the structure 602 at FIG. 6C, the method further includes selectively forming a metal precursor layer 616 on exposed surfaces of the patterned dielectric features 612 and the exposed portions of the substrate in gaps 614. The metal precursor layer 616 that lines the dielectric features 612 and the voids 614 may be prepared using precursor formation techniques and features described above with respect to FIGS. 1C and 2C.

As shown schematically in FIG. 6D, the method further includes a step that comprises converting the metal precursor layer 616 of FIG. 6C into a barrier layer 618 of FIG. 6D comprising at least one (e.g., semiconductor) chalcogenide to provide structure 603. The barrier layer 618 that lines the dielectric features 612 and the voids 614 may be prepared using the single stage barrier formation techniques and features described above with respect to FIG. 1D. Alternatively, the barrier layer 618 may be formed using the two-stage barrier formation techniques and features described above with respect to FIGS. 2D and 2E.

As schematically shown in structure 604 of FIG. 6E, the method further comprises filling the barrier-lined voids 614 of structure 603 of FIG. 6D with electrically conductive metal material 623 to provide structure 604 in FIG. 6E. Because metallization is achieved in FIG. 6E by filling voids 614 with metal material, the semiconductor field refers to this method as a damascene metallization strategy. The step of FIG. 6E may involve using damascene strategies including semi-damascene, single, damascene, and/or dual damascene techniques.

FIG. 6E shows the optional strategy of filling the voids 614 with an overburden 621 of metal material above line 622. FIG. 6F schematically shows the step of reducing the overburden 621 to provide a structure 606 preferably that is planar at line 622. In alternative modes of practice, the voids 614 are filled with metal material 623 without an overburden 621.

The method of FIGS. 6A to 6F shows a strategy by which the barrier layer 618 is formed prior to introduction of metal material to be protected by the barrier material. This sequence would be typical of damascene strategies. In metal patterning strategies described above, a barrier layer 618 generally is formed after some metal features are present.

After completing the steps shown in FIGS. 6E and 6F, the resultant structure 606 can be subjected to further processing, fabrication steps, or other handling as desired such as to proceed with further steps of fabrication.

The metal material 623 used to fill voids 614 in the method step of FIG. 6E may include one or more electrically conductive metal materials, including one or more transition metals, suitable for forming metal features such as contacts and interconnects in semiconductor devices. For example, the metal material 623 can include one or more of the following metals: copper (Cu), cobalt (Co), ruthenium (Ru), molybdenum (Mo), tungsten (W), nickel (Ni), hafnium (Hf), aluminum (Al), Scandium (Sc), Titanium (Ti), Vanadium (V), Manganese (Mn), Cobalt (Co), Nickel (Ni), Zinc (Zn), Yttrium (Y), Zirconium (Zr), Niobium (Nb), Technetium (Tc), Rhodium (Rh), Palladium (Pd), Silver (Ag), Hafnium (Hf), Tantalum (Ta), Rhenium (Re), Osmium (Os), Iridium (Ir), Platinum (Pt), Gold (Au), or combinations of these. Alloys of such metals may be used. For example, metal material(s) 623 can include a NiAl alloy, and/or a CuAl alloy. In preferred embodiments, metal material(s) 623 includes one or more of the following metals: copper (Cu) metal, aluminum (Al), cobalt (Co) metal, ruthenium (Ru) metal, molybdenum (Mo) metal, tungsten (W) metal, nickel (Ni) metal, or combinations of these.

Metal material(s) 623 can have the same or a different metal composition than the composition of the metal precursor layer 616 of FIG. 6D. Even when the metal compositions are the same (or even if they are different), the metal material(s) 623 and the metal precursor layer 616 can have a different crystallinity. In other modes of practice, the metal composition of the metal precursor layer 616 is different than the metal composition of the metal material(s) 623. Alternatively, the metal precursor layer 616 can have a same or similar crystallinity than the metal material(s) 623.

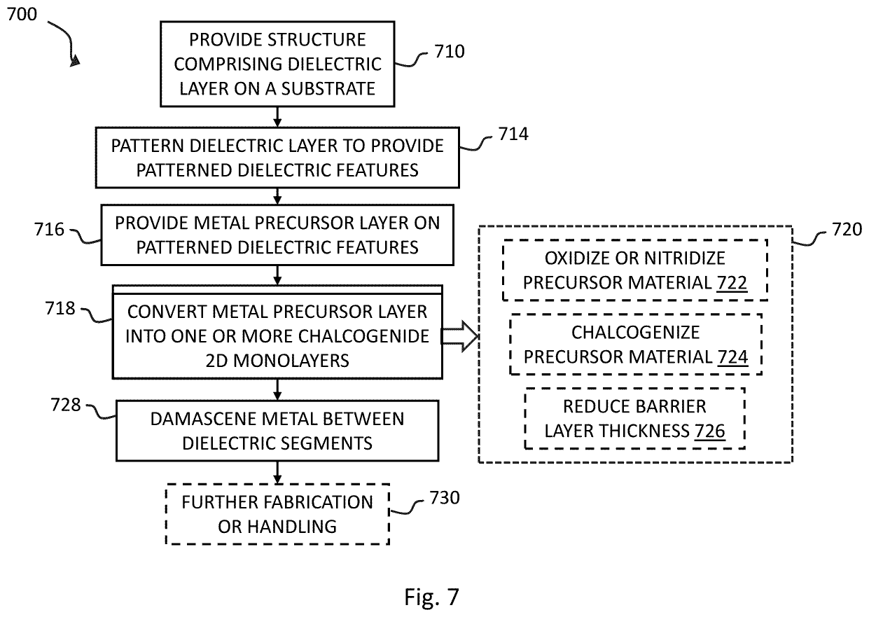

FIG. 7 is a flowchart that schematically shows a method 700 of integrating principles of the present invention into damascene metallization strategies. Method step 710 comprises providing a structure comprising a metal layer on a substrate. An illustrative embodiment of this method step 710 is schematically illustrated and described herein with respect to FIG. 6A.

Method step 714 comprises patterning the dielectric layer to provide patterned dielectric features. An illustrative embodiment of this method step 714 is schematically illustrated and described herein with respect to FIG. 6B.

Method step 716 comprises providing a metal precursor layer on the patterned dielectric features. An illustrative embodiment of this method step 716 is schematically illustrated and described herein with respect to FIG. 6C.

Method step 718 includes converting the metal precursor layer into one or more chalcogenide, 2D monolayers to thereby provide a barrier layer over the patterned dielectric features. Method step 718 may occur using a method comprising a single stage or two stages. In a single stage, step 720 shows that this conversion may occur by chalcogenizing the precursor material to form the desired barrier material. Illustrative embodiments of this single stage conversion are described herein with respect to FIGS. 1D and 3C. If a two-stage conversion is used, the conversion includes a first step of oxidizing and/or nitridizing at least a portion of the precursor material to provide modified precursor material. In a second stage, the modified precursor material is converted into a (e.g., semiconductor) chalcogenide. Illustrative embodiments of this two-stage conversion are described herein with respect to FIG. 2C to 2E and FIGS. 4A to 4C. Following other a single-stage or two-stage conversion, the barrier material optionally can be reduced in thickness to provide a barrier layer with the desired final thickness.

Step 730 shows that the metallization may be followed by further fabrication or handling.

The present invention has now been described with reference to several embodiments thereof. The foregoing detailed description and examples have been given for clarity of understanding only. No unnecessary limitations are to be understood therefrom. It will be apparent to those skilled in the art that many changes can be made in the embodiments described without departing from the scope of the invention. The implementations described above and other implementations are within the scope of the following claims.

What is claimed is:

1. A method of fabricating a semiconductor device comprising at least one barrier-protected metal feature, comprising the steps of:
a) forming a barrier layer by steps comprising:
1) providing a metal precursor layer, and
2) converting the metal precursor layer into one or more two-dimensional monolayers comprising at least one chalcogenide; and
b) causing the barrier layer to be in contact with at least one metal feature in a manner effective to provide the at least one barrier-protected metal feature.

2. The method of claim 1, wherein the at least one chalcogenide comprises at least one semiconductor chalcogenide.

3. The method of claim 1, wherein the at least one chalcogenide comprises a transition metal dichalcogenide.

4. The method of claim 1, further comprising the step of, prior to step a): providing a plurality of metal features on a substrate, and
wherein step a) comprises forming the metal precursor layer on the plurality of metal features.

5. The method of claim 1, wherein the at least one metal feature is formed after the barrier layer is formed.

6. The method of claim 1, wherein the at least one metal feature comprises a plurality of barrier-protected metal features, and wherein the method further comprises the steps of:
1) providing a substrate comprising a patterned dielectric layer comprising a plurality of voids,
2) forming the barrier layer on surfaces of the voids to provide barrier-lined voids, and
3) filling the barrier-lined voids with at least one metal composition to provide the plurality of barrier-protected metal features.

7. The method of claim 1, wherein the at least one metal feature comprises a plurality of metal features, and wherein the method further comprises the steps of:
1) forming the plurality of the metal features on a substrate, and
2) forming the barrier layer on the plurality of metal features to provide a plurality of barrier-protected metal features.

8. The method of claim 1, wherein step b) further comprises:
chalcogenizing at least a portion of the metal precursor layer under conditions effective to provide the barrier layer comprising the at least one two-dimensional monolayer to provide the barrier-protected metal feature,
wherein the at least one two-dimensional monolayer comprises a semiconductor chalcogenide.

9. A method for forming a semiconductor device, the method comprising:
a) providing a metal feature on a substrate;
b) forming a metal precursor layer on an exposed surface of the metal feature; and
c) chalcogenizing at least a portion of the metal precursor layer under conditions effective to provide a barrier layer comprising at least one two-dimensional monolayer to provide a barrier-protected metal feature, wherein the at least one two-dimensional monolayer comprises a metal chalcogenide.

10. The method of claim 9, wherein step c) comprises reacting the metal precursor layer with a reactant comprising at least one chalcogen.

11. The method of claim 10, wherein the reactant comprises sulfur(S), selenium (Se), and/or tellurium (Te).

12. The method of claim 11, wherein the reactant is selected from the group consisting of: H₂S, SO₂, (CH₃)₂S, (CH₃)₂S₂, (CH₃CH₂)₂S, and/or (CH₃CH₂)₂S₂.

13. The method of claim 9, further comprising:
prior to step c), modifying at least a portion of the metal precursor layer by exposure to at least one of: a reducing gas, an oxygen-containing gas, a nitrogen-containing gas, or an oxygen- and nitrogen-containing gas.

14. The method of claim 13, wherein the modifying step is done selectively on a portion of the metal precursor layer, and wherein the method further comprises the step of selectively chalcogenizing the selectively modified metal precursor layer to form the at least one two-dimensional monolayer.

15. The method of claim 9, wherein the metal feature comprises at least one metal material selected from the group consisting of: copper (Cu) metal, cobalt (Co) metal, ruthenium (Ru) metal, molybdenum (Mo) metal, tungsten (W) metal, nickel (Ni) metal, aluminum (Al), niobium (Nb), iridium (Ir), rhodium (Rh) metal, alloys thereof, and combinations thereof.

16. The method of claim 9, wherein the metal precursor layer comprises at least one metal material selected from the group consisting of: ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, alloys thereof, and combinations thereof.

17. The method of claim 9, wherein the barrier layer and the barrier-protected metal feature comprise at least one different metal or element.

18. The method of claim 9, wherein the metal chalcogenide is a dichalcogenide that includes one or more dichalcogenides of the formula MX₂, wherein M is a metal and X is one or more of S, Se, and/or Te.

19. The method of claim 9, further comprising, following step c):
depositing a dielectric material on exposed surfaces of the barrier-protected metal feature and/or the substrate.

20. The method of claim 19, further comprising selectively depositing an additional feature on an exposed surface of the dielectric material, wherein the additional feature comprises a dielectric material.

21. A semiconductor device, comprising:
a metal feature on a substrate; and
a barrier layer in contact with a surface of the metal feature, the barrier layer comprising one or more monolayers of two-dimensional material comprising a chalcogenide, wherein the barrier is formed on the surface of the metal feature by:
providing a metal precursor layer on the surface of the metal feature, and
converting the metal precursor layer into the one or more two-dimensional monolayers comprising the chalcogenide.

22. The device of claim 21, wherein the metal feature comprises: copper (Cu) metal, cobalt (Co) metal, ruthenium (Ru) metal, molybdenum (Mo) metal, tungsten (W) metal, nickel (Ni) metal, aluminum (Al) metal, alloys thereof, and combinations thereof.

23. The device of claim 21, wherein the barrier layer is formed by chalcogenizing a metal precursor layer comprising: ruthenium (Ru) metal, molybdenum (Mo) metal, tungsten (W) metal, copper (Cu) metal, cobalt (Co) metal, tantalum (Ta) metal, titanium (Ti) metal, hafnium (Hf) metal, alloys thereof, and combinations thereof.

24. The device of claim 21, wherein the two-dimension material contains a transition metal dichalcogenide.

25. The device of claim 21, wherein the chalcogenide is a dichalcogenide that includes one or more dichalcogenides of the formula MX₂, wherein M is a metal and X is one or more of S, Se, and/or Te.

26. The device of claim 21, further comprising a dielectric material between the metal features.
